(19) United States
(12) Patent Application Publication
(10) Pub. No.: US 2024/0221817 A1
(43) Pub. Date: Jul. 4, 2024

(54) WRITE DATA SIGNAL DELAY CONTROL METHOD AND APPARATUS, DEVICE, AND MEDIUM

(71) Applicant: Tencent Technology (Shenzhen) Company Limited, Shenzhen (CN)

(72) Inventor: Peng QIANG, Shenzhen (CN)

(21) Appl. No.: 18/604,366

(22) Filed: Mar. 13, 2024

Related U.S. Application Data
(63) Continuation of application No. PCT/CN2023/081939, filed on Mar. 16, 2023.

(30) Foreign Application Priority Data
May 20, 2022 (CN) 202210548827.0

(51) Int. Cl. G11C 11/4076; G11C 11/4091; G11C 11/4093

(52) U.S. Cl. CPC G11C 11/4076; G11C 11/4091; G11C 11/4093

(57) ABSTRACT

This application relates to a write data signal delay control method performed by a computer device. The method includes: configuring an operating mode of a register circuit in a memory by using a host, to obtain a training register that supports reading and writing; transmitting a sample write data signal to the memory by using the host; sampling the sample write data signal based on a sampling signal by using the memory, and caching a sampled write data signal obtained from the sampling into the training register; and performing delay adjustment training on a write data delay control circuit arranged on the host based on the sample write data signal when the sampled write data signal read by the host from the training register is inconsistent with the sample write data signal.

### CROSS-REFERENCE TO RELATED APPLICATIONS

This application is a continuation application of PCT Patent Application No. PCT/CN2023/081939, entitled “WRITE DATA SIGNAL DELAY CONTROL METHOD AND APPARATUS, DEVICE, AND MEDIUM” filed on Mar. 16, 2023, which claims priority to Chinese Patent Application No. 2022105488270, entitled “WRITE DATA SIGNAL DELAY CONTROL METHOD AND APPARATUS, DEVICE, AND MEDIUM” filed with the China National Intellectual Property Administration on May 20, 2022, all of which is incorporated by reference in its entirety.

### FIELD OF THE TECHNOLOGY

This application relates to the field of computer technologies, and in particular, to a write data signal delay control method and apparatus, a device, and a medium.

### BACKGROUND OF THE DISCLOSURE

In a high-bandwidth memory system, a host in the high-bandwidth memory system transmits a write data signal to a memory in the high-bandwidth memory system, so that corresponding write operation control of the memory may be implemented. However, during transmission of the write data signal to the memory by the host, since the transmission of the write data signal may be affected by factors such as an environmental change and a crosstalk between signals, an offset of the write data signal from a sampling signal in the memory may be caused, and then an error in sampling of write data occurs. If the error in the sampling of the write data occurs, an error may occur in a write operation on the memory performed by the host, which may cause an error to occur in data written to the memory, and reduce operation stability of the memory.

### SUMMARY

Based on this, a write data signal delay control method and apparatus, a device, and a medium need to be provided to resolve the foregoing technical problems.

According to a first aspect, this application provides a write data signal delay control method, performed by a computer device, the method including:
configuring an operating mode of a register circuit in a memory by using a host, to obtain a training register that supports reading and writing;
transmitting a sample write data signal to the memory by using the host;
sampling the sample write data signal based on a sampling signal by using the memory, and caching a sampled write data signal obtained from the sampling into the training register; and
performing delay adjustment training on a write data delay control circuit arranged on the host based on the sample write data signal when the sampled write data signal read by the host from the training register is inconsistent with the sample write data signal.

According to a second aspect, this application provides a computer device, including a memory and one or more processors, the memory having computer-readable instructions stored therein that, when executed by the one or more processors, cause the computer device to implement the operations in the method embodiments of this application when executing the computer-readable instructions.

According to a third aspect, this application provides one or more non-transitory computer-readable storage media, having computer-readable instructions stored therein, the computer-readable instructions, when executed by one or more processors of a computer device, causing the computer device to implement the operations in the method embodiments of this application.

Details of one or more embodiments of this application are provided in the accompanying drawings and descriptions below. Other features, objectives, and advantages of this application become apparent from the specification, the accompanying drawings, and the claims.

To describe the technical solutions of the embodiments of this application more clearly, the following briefly describes the accompanying drawings required for describing the embodiments. Apparently, the accompanying drawings in the following description show merely some embodiments of this application, and a person of ordinary skill in the art may still derive other accompanying drawings from these accompanying drawings without creative efforts.

### BRIEF DESCRIPTION OF THE DRAWINGS

FIG. 1 is an application environment diagram of a write data signal delay control method according to an embodiment.

FIG. 2 is a schematic flowchart of a write data signal delay control method according to an embodiment.

FIG. 3 is a schematic diagram of a composition structure of a write data signal according to an embodiment.

FIG. 4 is a schematic diagram of transmission timing of a write instruction according to an embodiment.

FIG. 5 is a schematic diagram of a format of a write data signal according to an embodiment.

FIG. 6 is a schematic diagram of a format of a write data signal when a burst length is 2 according to an embodiment.

FIG. 7 is a schematic diagram of a format of a write data signal when a burst length is 4 according to an embodiment.

FIG. 8 is a schematic diagram of a transmission process of a write data signal according to an embodiment.

FIG. 9 is a schematic diagram of transmission timing of a read instruction according to an embodiment.

FIG. 10 is a schematic diagram of alignment of a write data signal with a sampling edge of a sampling signal according to an embodiment.

FIG. 11 is a schematic diagram of a configuration description table of a mode register according to an embodiment.

FIG. 12 is a schematic diagram of distribution of each subsample signal in a write data signal according to an embodiment.

FIG. 13 is a basic structural diagram of a write data delay control circuit according to an embodiment.

FIG. 14 is a schematic diagram of each subsample signal in a write data signal according to an embodiment.

FIG. 15 is a schematic diagram of alignment of each subsample signal in a write data signal with a sampling edge of a sampling signal according to an embodiment.

FIG. 16 is a schematic diagram of a process of performing single-circuit delay adjustment training on each subcircuit according to an embodiment.

FIG. 17 is a schematic structural diagram of each subcircuit in a write data delay control circuit according to an embodiment.

FIG. 18 is a basic structural diagram of a training circuit for write data signal delay control according to an embodiment.

FIG. 19 is a schematic flowchart of a write data signal delay control method according to another embodiment.

FIG. 20 is a structural block diagram of a write data signal delay control apparatus according to an embodiment.

FIG. 21 is an internal structure diagram of a computer device according to an embodiment.

FIG. 22 is an internal structure diagram of a computer device according to another embodiment.

### DESCRIPTION OF EMBODIMENTS

To make objectives, technical solutions, and advantages of this application clearer, this application is further described in detail below with reference to accompanying drawings and embodiments. It is to be understood that, the specific embodiments described herein are merely intended to explain this application, but are not intended to limit this application.

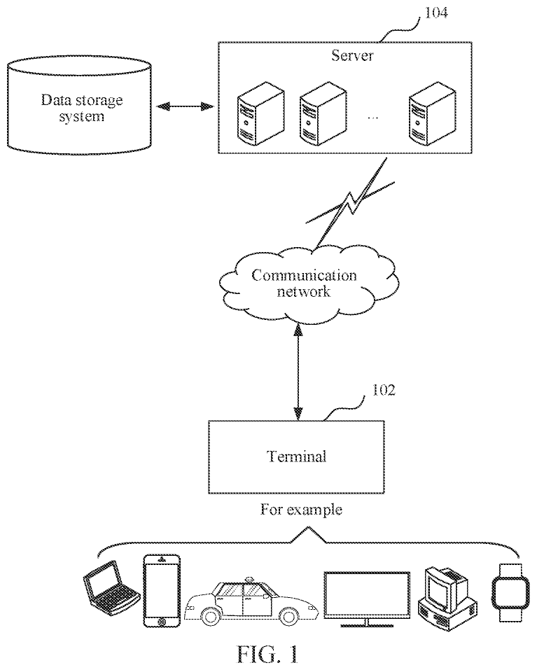

A write data signal delay control method provided in this application may be applied to an application environment shown in FIG. 1. A terminal 102 communicates with a server 104 through a network. A data storage system may store data to be processed by the server 104. The data storage system may be integrated on the server 104, or may be arranged on the cloud or another server. The terminal 102 may be, but is not limited to, various desktop computers, notebook computers, smartphones, tablet computers, Internet of Things devices, and portable wearable devices. The Internet of Thing devices may be a smart speaker, a smart television, a smart air conditioner, a smart onboard device, and the like. The portable wearable device may be a smartwatch, a smart bracelet, a head-mounted device, and the like. The server 104 may be an independent physical server, or may be a server cluster formed by a plurality of physical servers or a distributed system, and may further be a cloud server providing basic cloud computing services such as cloud service, a cloud database, cloud computing, a cloud function, cloud storage, a network service, cloud communication, a middleware service, a domain name service, a security service, a CDN, and a big data and artificial intelligence platform. The terminal 102 and the server 104 may be directly or indirectly connected through wired or wireless communication, which is not limited in this application.

A high-bandwidth memory system including a host and a memory is deployed in the server 104. The server 104 may configure an operating mode of a register circuit in a memory by using the host, to obtain a training register that supports reading and writing. The server 104 transmits a sample write data signal to the memory by using the host, samples the sample write data signal based on a sampling signal by using the memory, and caches a sampled write data signal obtained from the sampling into the training register. When the sampled write data signal read by the host from the training register is inconsistent with the sample write data signal, the server 104 may perform delay adjustment training on a write data delay control circuit arranged on the host based on the sample write data signal, to obtain a trained write data delay control circuit. The server 104 may perform signal offset adjustment on an inputted write data signal by using the trained write data delay control circuit, to obtain a target write data signal aligned with a sampling edge of the sampling signal. The target write data signal is to be written to the memory.

It may be understood that the host in the server 104 may generate a sample write data signal and transmit the sample write data signal to the memory in the server 104, to perform subsequent delay adjustment training. It may further be understood that the terminal 102 may alternatively generate a sample write data signal and transmit the sample write data signal to the server 104. Then the server 104 may receive the sample write data signal by using the host, and transmit the received sample write data signal to the memory in the server 104, to perform subsequent delay adjustment training. This is not limited in this embodiment. It may be understood that, the application scenario in FIG. 1 is merely a schematic illustration, and is not limited thereto.

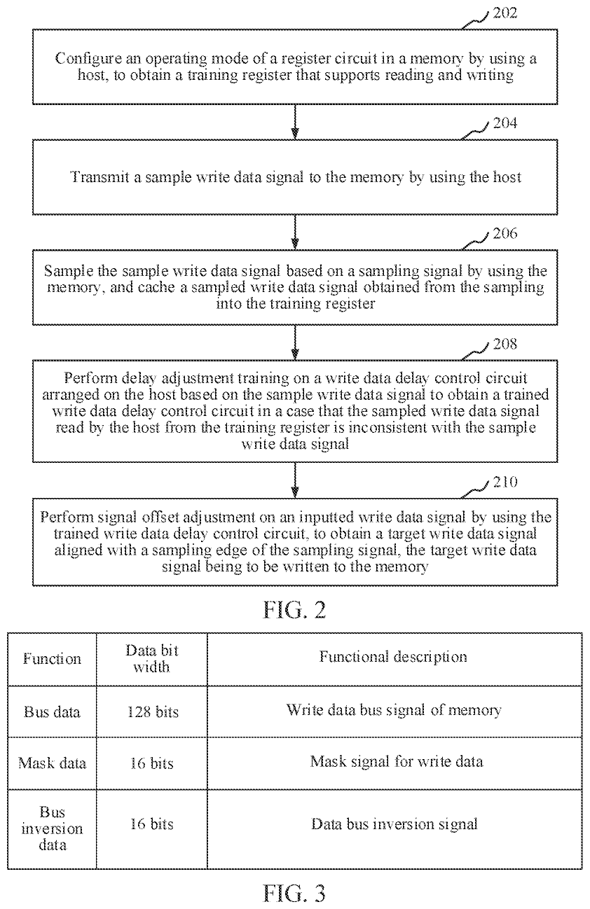

In an embodiment, as shown in FIG. 2, a write data signal delay control method is provided. The method may be applied to a computer device. The computer device may be a terminal or a server. The method may be performed by the terminal or the server independently, or may be implemented through interaction between the terminal and the server. This embodiment is described by using an example in which the method is applied to the computer device, including the following steps:

Step 202: Configure an operating mode of a register circuit in a memory by using a host, to obtain a training register that supports reading and writing.

The register circuit is an independent circuit in the memory, which can be configured in a plurality of operating modes. For example, the register circuit can be configured in a read-write mode, a read-only mode, a write-only mode, and the like. It may be understood that the register circuit is configured in the read-write mode, a register that supports reading and writing may be obtained, that is, the training register that supports reading and writing. It may be understood that the training register is a register configured to cache data in a training stage. The register circuit is configured in the read-only mode, so that a register that supports reading may be obtained. The register circuit is configured in the write-only mode, so that a register that supports writing may be obtained.

Specifically, the computer device includes a host and a memory. The computer device may configure the operating mode of the register circuit in the memory by using the host, to obtain the training register that supports reading and writing. It may be understood that the computer device may configure the operating mode of the register circuit in the memory in the read-write mode by using the host, to obtain the training register that supports reading and writing.

In an embodiment, the host and the memory are components of a high-bandwidth memory system. The high-bandwidth memory system is deployed in the computer device.

In an embodiment, the memory may be a dynamic random access memory (DRAM), or may be a RAM. This embodiment of this application is merely for illustration, and does not constitute a specific limitation on a type of the memory.

Step 204: Transmit a sample write data signal to the memory by using the host.

The sample write data signal is a write data signal used for training the write data delay control circuit arranged on the host in the training stage. It may be understood that the sample write data signal is sample data used for training the write data delay control circuit. The write data delay control circuit is a circuit configured to perform delay control on the write data signal to control alignment of the write data signal with the sampling edge of the sampling signal of the memory, so that the memory may correctly sample the write data signal based on the sampling signal. The sampling signal is a clock signal in the memory for sampling the write data signal transmitted by the host.

Specifically, the computer device may obtain the sample write data signal by using the host, and transmit the sample write data signal to the memory by using the host.

In an embodiment, as shown in FIG. 3, the write data signal includes three parts: a write data bus signal, a mask signal, and a data bus inversion signal. A data bit width of the write data bus signal is 128 bits, a data bit width of the mask signal is 16 bits, and a data bit width of the data bus inversion signal is 16 bits.

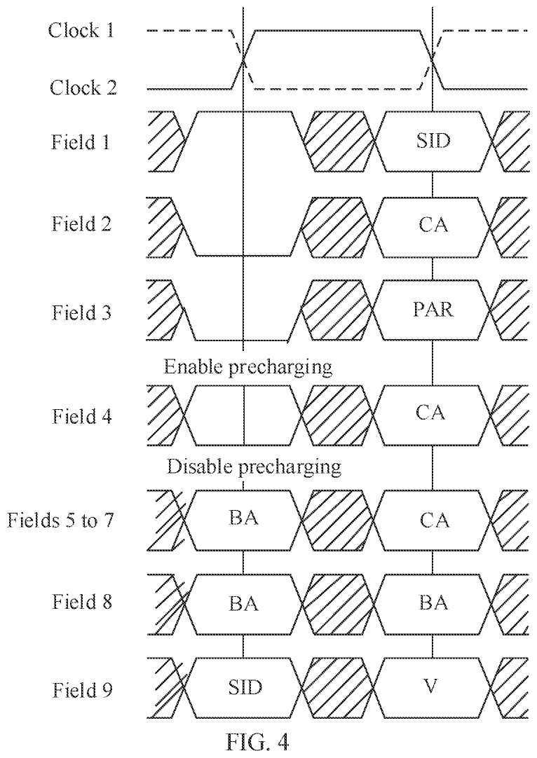

In an embodiment, before the computer device transmits the sample write data signal to the memory by using the host, the host first transmits a write instruction to the memory. The transmission of the write instruction needs to follow the timing shown in FIG. 4. It may be learned from FIG. 4 that the write instruction includes 9 fields, where an SID represents a stack identification number, a CA field represents a column address, a BA field represents a Bank address, a PAR field represents an instruction check field, and a V field may represent 1 or 0, that is, a high level or a low level. Clock 1 and clock 2 are two differential clocks.

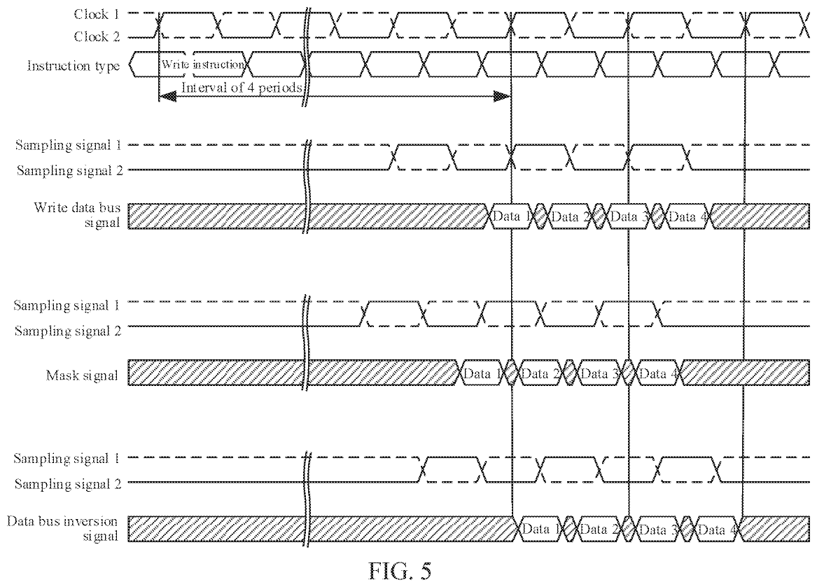

In an embodiment, as shown in FIG. 5, the write data signal includes three parts: a write data bus signal, a mask signal, and a data bus inversion signal. The computer device transmits the write data signal to the memory by using the host again at an interval of 4 periods after transmitting the write instruction to the memory by using the host, that is, the write data bus signal, the mask signal, and the data bus inversion signal. Each part of the write data signal corresponds to a respective sampling signal. Each part of the write data signal may include a plurality of sets of data (for example, 4 sets, that is, data 1, data 2, data 3, and data 4).

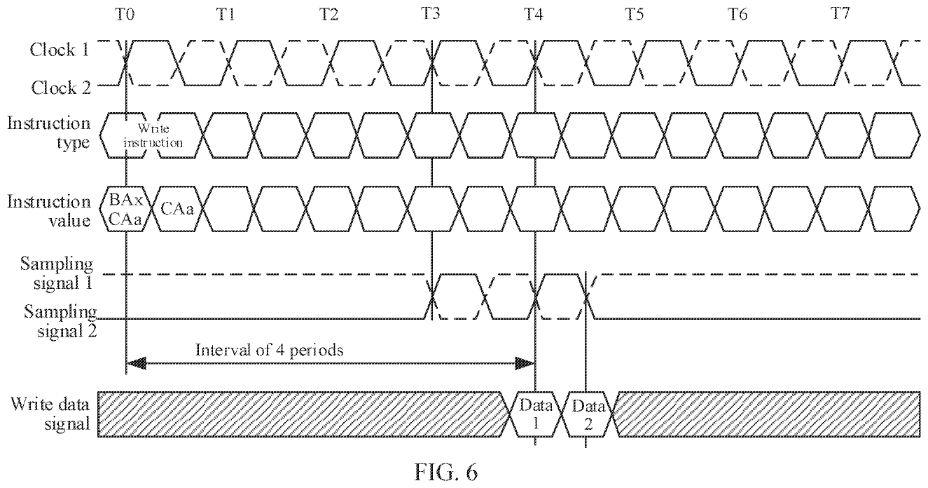

In an embodiment, that the computer transmits the write data signal to the memory by using the host is implemented based on a burst form. To be specific, every time the write data signal is transmitted, a plurality of sets of write data signals are transmitted together. As shown in FIG. 6, a burst length of the write data signal transmitted by the computer to the memory by using the host is 2. The computer device may transmit the write instruction to the memory at a moment T0 by using the host. After 4 periods of transmission of the write instruction, that is, at a moment T4, the computer device may transmit 2 sets of write data signals (that is, the data 1 and the data 2) to the memory by using the host. Numerical values of the write instruction transmitted by the host to the memory include BAx (a Bank address) and CAa (a column address).

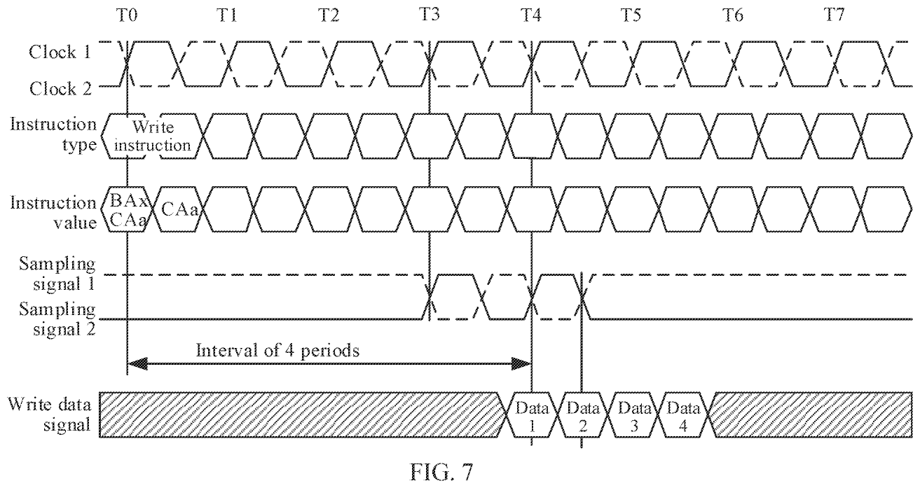

In an embodiment, as shown in FIG. 7, a burst length of the write data signal transmitted by the computer to the memory by using the host is 4. The computer device may transmit the write instruction to the memory at a moment T0 by using the host. After 4 periods of transmission of the write instruction, that is, at a moment T4, the computer device may transmit 4 sets of write data signals (that is, the data 1, the data 2, the data 3, and the data 4) to the memory by using the host. Numerical values of the write instruction transmitted by the host to the memory include BAx (a Bank address) and CAa (a column address).

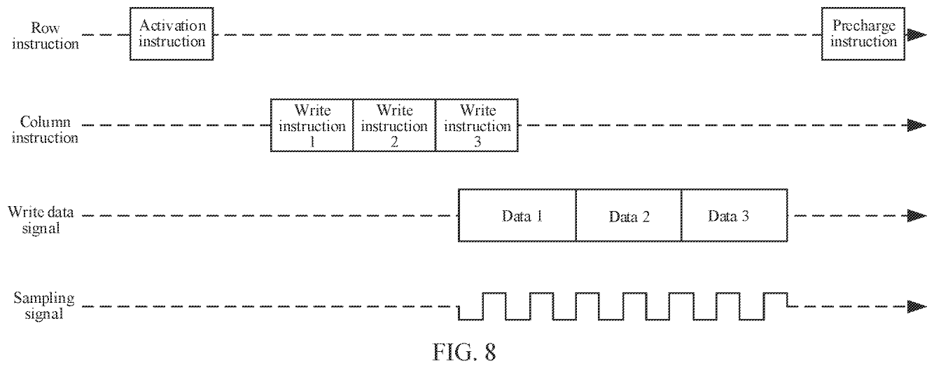

In an embodiment, as shown in FIG. 8, the computer device may transmit an activation instruction to the memory by using the host to start current data writing. The computer device may transmit write instructions (that is, a write instruction 1, a write instruction 2, and a write instruction 3) to the memory by using the host after transmitting the activation instruction. Then the computer device may transmit write data signals (that is, data 1, data 2, and data 3) to the memory by using the host. During transmission of the write data signal, the host may transmit a write data selection pulse signal matching the write data signal to the memory together as the sampling signal. Finally, the computer device may transmit a precharging instruction to the memory by using the host to end the current data writing.

Step 206: Sample the sample write data signal based on the sampling signal by using the memory, and cache a sampled write data signal obtained from the sampling into the training register.

The sampled write data signal is a write data signal sampled by the memory based on the sampling signal.

Specifically, the computer device also transmits the corresponding sampling signal to the memory while transmitting the sample write data signal to the memory by using the host. Then the computer device may sample the sample write data signal based on the received sampling signal by using the memory, and cache a sampled write data signal obtained from the sampling into the training register.

In an embodiment, the computer device may transmit the sample write data signal to the memory by using the host along with the write data selection pulse signal matching the sample write data signal. The memory may use the received write data selection pulse signal as the sampling signal, and sample, based on the sampling signal, the sample write data signal transmitted by the host, to obtain the sampled write data signal. It may be understood that since the sampling signal is the write data selection pulse signal that matches the sample write data signal, sampling accuracy of the write data signal may be improved by sampling the sample write data signal based on the sampling signal.

Step 208: Perform delay adjustment training on a write data delay control circuit arranged on the host based on the sample write data signal to obtain a trained write data delay control circuit when the sampled write data signal read by the host from the training register is inconsistent with the sample write data signal.

Specifically, the computer device may read the sampled write data signal from the training register of the memory by using the host, and compare the sampled write data signal read by the host from the training register with the sample write data signal transmitted by the host to the memory. If the sampled write data signal is inconsistent with the sample write data signal, it means that an offset exists between the sample write data signal and the sampling edge of the sampling signal during the transmission, the sample write data signal is not correctly sampled by the sampling signal, and then the sample write data signal is not successfully cached to the training register. In this case, to ensure that a subsequent write data signal is aligned with the sampling edge of the sampling signal, the computer device may perform the delay adjustment training on the write data delay control circuit arranged on the host based on the sample write data signal, to obtain the trained write data delay control circuit.

It may be understood that the write data signal is aligned with the sampling edge of the sampling signal, which specifically means that a signal center of the write data signal is aligned with the sampling edge of the sampling signal of the memory.

In an embodiment, the sampling edge of the sampling signal includes a rising edge of the sampling signal and a falling edge of the sampling signal. If the computer device samples the write data signal through the rising edge of the sampling signal of the memory, the signal center of the write data signal is aligned with the rising edge of the sampling signal of the memory. If the computer device samples the write data signal through the falling edge of the sampling signal of the memory, the signal center of the write data signal is aligned with the falling edge of the sampling signal of the memory. It may be understood that, since the sampling edge of the sampling signal includes the rising edge and the falling edge, determining, at a finer granularity, whether the rising edge of the sampling signal or the falling edge of the sampling signal is used to sample the write data signal may avoid misalignment, thereby further improving sampling accuracy of the write data signal.

In an embodiment, the sample write data signal includes a plurality of subsample signals, and the write data delay control circuit arranged on the host includes a plurality of subcircuits. One of the subcircuits is configured to control a delay of one of the subsample signals. The computer device may perform delay adjustment training on the plurality of subcircuits arranged on the host based on the plurality of subsample signals, to obtain a trained write data delay control circuit.

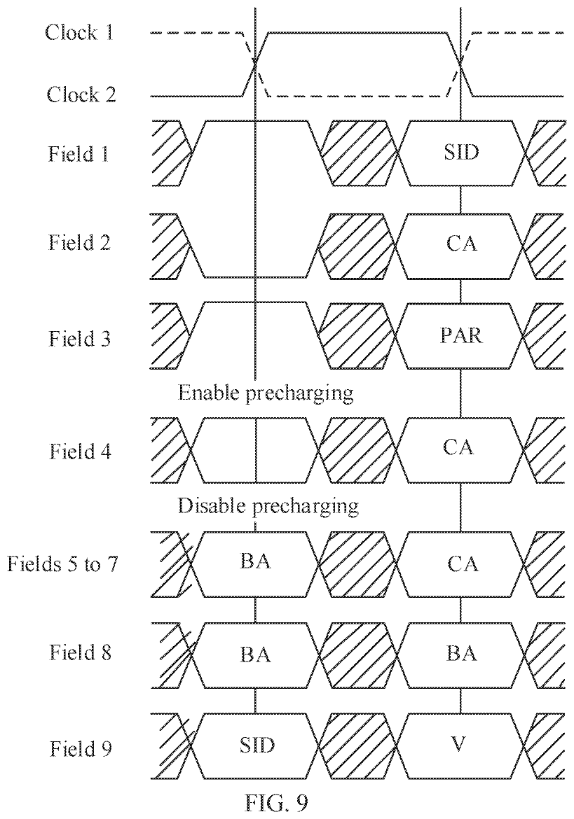

In an embodiment, before the computer device reads the sampled write data signal from the training register of the memory by using the host, the host first transmits a read instruction to the memory. The transmission of the read instruction needs to follow the timing shown in FIG. 9. As shown in FIG. 9, the read instruction includes 9 fields, where an SID represents a stack identification number, a CA field represents a column address, a BA field represents a Bank address, a PAR field represents an instruction check field, and a V field may represent 1 or 0, that is, a high level or a low level.

Step 210: Perform signal offset adjustment on an inputted write data signal by using the trained write data delay control circuit, to obtain a target write data signal aligned with a sampling edge of the sampling signal. The target write data signal is to be written to the memory.

The inputted write data signal is a write data signal obtained by the host in an actual application scenario after the training stage. The target write data signal is a write data signal on which offset adjustment is performed and aligned with the sampling edge of the sampling signal.

Specifically, in an actual application stage after the delay adjustment training, the computer device may obtain the write data signal in the actual application scenario by using the host, and input the obtained write data signal into the trained write data delay control circuit, so as to perform signal offset adjustment on the inputted write data signal by using the trained write data delay control circuit, and obtain the target write data signal that is aligned with the sampling edge of the sampling signal in the memory. Then the computer device may transmit the adjusted target write data signal to the memory, and the memory may sample the target write data signal based on the sampling signal, to write the target write data signal to the memory.

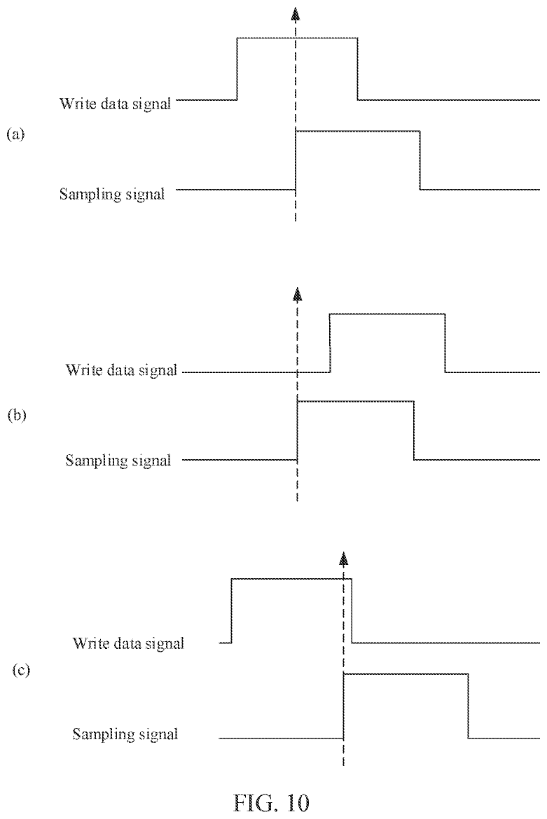

In an embodiment, the computer device samples the write data signal by using the rising edge of the sampling signal of the memory. As shown in FIG. 10, a center of the write data signal in (a) is exactly aligned with the rising edge of the sampling signal. In this case, the memory may accurately sample the write data signal based on the sampling signal. An offset exists between a center of the write data signal in (b) and the rising edge of the sampling signal, and even the rising edge of the sampling signal has drifted out of a data window of the write data signal. In this case, the memory cannot sample the write data signal based on the sampling signal. An offset also exists between a center of the write data signal in (c) and the rising edge of the sampling signal. In this case, the memory may not accurately sample the write data signal based on the sampling signal.

In the foregoing write data signal delay control method, the operating mode of the register circuit in the memory is configured by using the host, to obtain the training register that supports reading and writing. The sample write data signal is transmitted to the memory by using the host. The sample write data signal is sampled based on the sampling signal by using the memory, the sampled write data signal obtained from the sampling is cached in the training register, and the sampled write data signal is compared with the sample write data signal transmitted by the host. If the sampled write data signal read by the host from the training register is inconsistent with the sample write data signal, it means that an offset exists between the sample write data signal transmitted by the host and the sampling signal of the memory. In this case, the delay adjustment training may be performed on the write data delay control circuit arranged on the host based on the sample write data signal, to obtain the trained write data delay control circuit. Then in an actual application process, the signal offset adjustment may be performed on the inputted write data signal by using the trained write data delay control circuit, and the adjusted target write data signal may be transmitted to the memory. In this way, the target write data signal received by the memory may be aligned with the sampling edge of the sampling signal of the memory, so that the memory may correctly sample the write data signal transmitted by the host, thereby ensuring correctness of the data written to the memory, and improving operation stability of the memory.

In an embodiment, the configuring an operating mode of a register circuit in a memory by using a host, to obtain a training register that supports reading and writing includes: setting a value of a mode register in the memory to a target value by using the host, the mode register being a register configured to configure the operating mode of the register circuit; the target value being a value corresponding to a read-write mode supported by the register circuit; and controlling, by using the target value, the register circuit to operate in the read-write mode, to obtain the training register that supports reading and writing.

Specifically, the mode register is deployed in the memory. The mode register may configure the operating mode of the register circuit in the memory. It may be understood that the computer device may set a value of the mode register in the memory to the target value corresponding to the read-write mode by using the host, then control the register circuit to operate in the read-write mode by using the target value, and use, as the training register that supports reading and writing, the register circuit operating in the read-write mode.

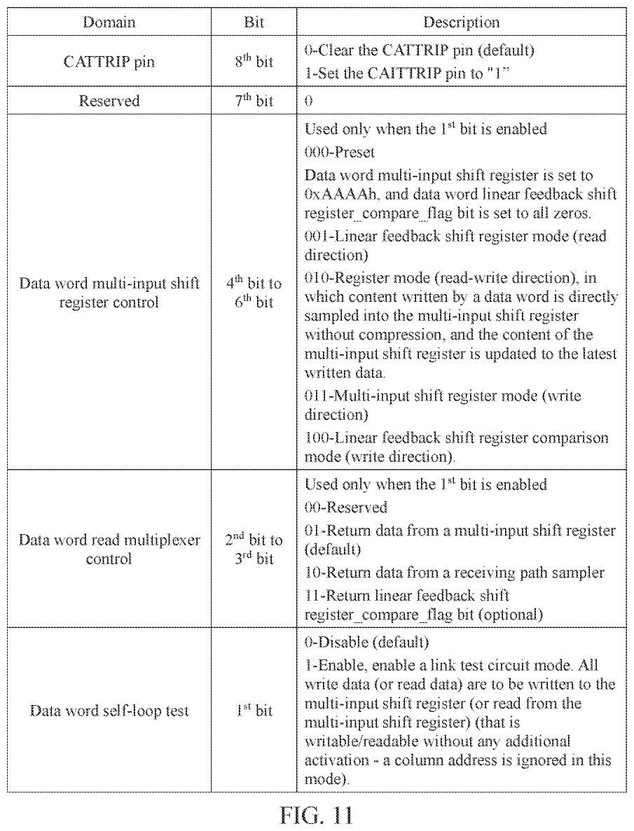

In an embodiment, configuration of an operating mode of the mode register is described as shown in FIG. 11. The value of the mode register includes 8 bits of data. The 1 st bit is configured for a data word self-loop test, the 2nd bit and the 3rd bit are configured for data word read multiplexer control, the 4th bit to the 6th bit are configured for data word multi-input shift register control, the 7th bit is a reserved bit, and the 8th bit is configured for a CATTRIP pin of the memory. For example, the mode register is configured to an 8-bit binary value, that is, 00000001, and a default value in the register circuit may be reset to a hexadecimal value, that is, 0xAAAAAh. The mode register is configured to an 8-bit binary value, that is, 00010011, and the operating mode of the register circuit may be configured as the register mode (a read-write direction), that is, a read-write mode, to obtain the training register. It may be understood that if the host writes new data to the memory, the newly written data may overwrite an original default value of 0xAAAAAh.

In the foregoing embodiments, since the mode register in the memory may be configured to configure the operating mode of the register circuit, configuration efficiency and configuration accuracy of the register circuit may be improved by configuring the value of the mode register in the memory to configure the operating mode of the register circuit.

In an embodiment, the sample write data signal includes a plurality of subsample signals. The write data delay control circuit arranged on the host includes a plurality of subcircuits. One of the subcircuits is configured to control a delay of one of the subsample signals. The performing delay adjustment training on a write data delay control circuit arranged on the host based on the sample write data signal, to obtain a trained write data delay control circuit includes: performing, for each subcircuit in the write data delay control circuit, single-circuit delay adjustment training on the subcircuit based on the subsample signal corresponding to the subcircuit, to obtain a trained initial subcircuit, the subsample signal on which the signal offset adjustment is performed by using the initial subcircuit being aligned with the sampling edge of the sampling signal; and performing multi-circuit delay adjustment training on each initial subcircuit based on the plurality of subsample signals, to obtain the trained write data delay control circuit, the trained write data delay control circuit including a plurality of trained target subcircuits, each subsample signal on which the signal offset adjustment is performed by using each of the target subcircuits being aligned with the same sampling edge of the sampling signal.

The initial subcircuit is an initial trained circuit obtained by performing single-circuit delay adjustment training on the subcircuit. The target subcircuit is a final circuit obtained by performing advanced delay adjustment training on the initial subcircuit.

Specifically, the computer device may perform, for each subcircuit in the write data delay control circuit, single-circuit delay adjustment training on the subcircuit based on the subsample signal corresponding to the subcircuit, to obtain a trained initial subcircuit. It may be understood that if the computer device inputs the subsample signal into the initial subcircuit, the subsample signal after the signal offset adjustment performed by using the initial subcircuit is aligned with the sampling edge of the sampling signal. The computer device may perform multi-circuit delay adjustment training on each initial subcircuit based on the plurality of subsample signals, to obtain a plurality of trained target subcircuits, and determine the trained write data delay control circuit based on the plurality of trained target subcircuits. It may be understood that if the computer device inputs the subsample signal into the target subcircuit, each subsample signal on which the signal offset adjustment is performed by using each target subcircuit is aligned with the same sampling edge of the sampling signal.

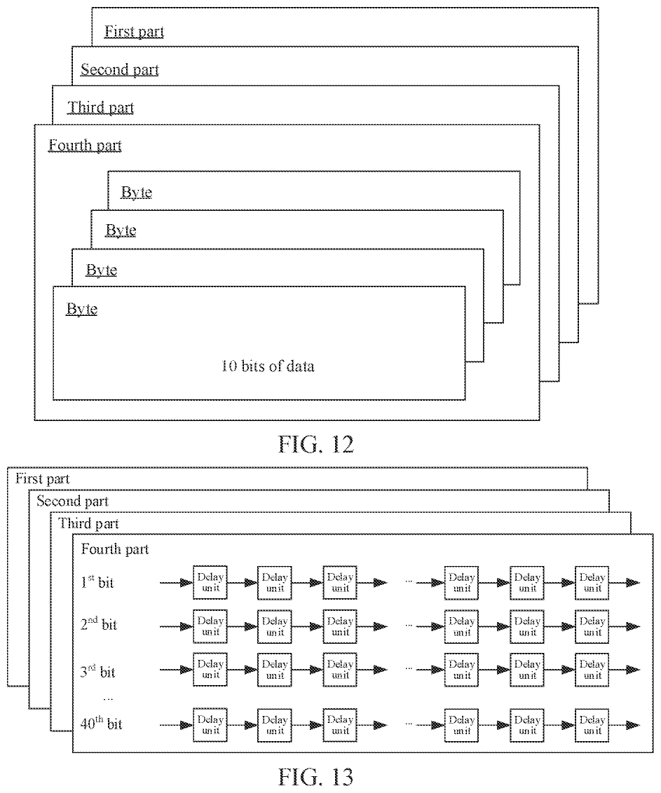

In an embodiment, as shown in FIG. 12, the sample write data signal includes 160 subsample signals. It may be understood that the sample write data signal includes 160 bits of subsample signals. The 160 bits of the sample write data signal may be divided into four parts: a first part, a second part, a third part, and a fourth part. Each part includes four byte spaces, and each byte space includes 10 bits of data. In other words, each part includes 40 bits of data. It may be understood that the sample write data signal consists of 128 bits of write data bus signals, 16 bits of mask signals, and 16 bits of data bus inversion signals.

In an embodiment, as shown in FIG. 13, the 160 bits of the sample write data signal may be divided into four parts: a first part, a second part, a third part, and a fourth part. Each part includes 40 bits of subsample signals. The write data delay control circuit arranged on the host includes 160 subcircuits. One subcircuit includes a plurality of write data delay control units, and the subcircuit is configured to control delay of one subsample signal.

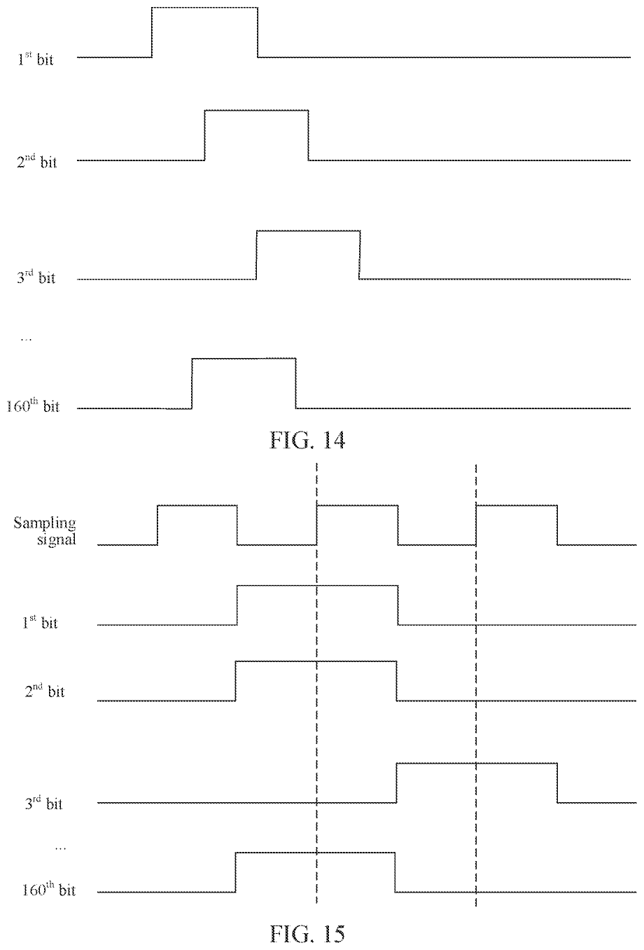

In an embodiment, as shown in FIG. 14, the sample write data signal includes 160 bits of subsample signals, and the write data delay control circuit includes 160 subcircuits, one subcircuit being configured to control a delay of one subsample signal. For each of the 160 subcircuits, single-circuit delay adjustment training is performed on the subcircuit based on the subsample signal corresponding to the subcircuit, to obtain a trained initial subcircuit, the subsample signal after the signal offset adjustment performed by using the initial subcircuit being aligned with the sampling edge of the sampling signal. It may be understood that the 160 bits of subsample signals after the signal offset adjustment performed by using the initial subcircuit are only aligned with each sampling edge of the sampling signal, but not necessarily aligned with the same sampling edge of the sampling signal. As shown in FIG. 15, the 160 bits of subsample signals are not aligned with the same sampling edge of the sampling signal. In this case, the training is not over yet, and adjustment training still needs to be performed on each subcircuit, until the end of the adjustment training when the 160 bits of subsample signals are aligned with the same sampling edge of the sampling signal, to obtain the trained write data delay control circuit.

In the foregoing embodiments, the single-circuit delay adjustment training is first performed on each subcircuit in the write data delay control circuit to obtain an initial subcircuit, so that each subsample signal in the sample write data signal is aligned with the sampling edge of the sampling signal. Since the sampling edges of the sampling signals aligned with the subsample signals are not necessarily the same sampling edge, to ensure that the sampling edges of the sampling signals aligned with the subsample signals are the same sampling edge, multi-circuit delay adjustment training may be further performed on the initial subcircuit obtained through the single-circuit delay adjustment training, so that the sampling edges of the sampling signals aligned with the subsample signals are the same sampling edge, thereby improving a training effect of the write data delay control circuit.

In an embodiment, the sampled write data signal includes a plurality of subsampled signals respectively corresponding to the plurality of subsample signals. The performing multi-circuit delay adjustment training on each initial subcircuit based on the plurality of subsample signals, to obtain the trained write data delay control circuit includes: continuously performing the delay adjustment training on an initial subcircuit for advanced training based on initial adjustment information of the initial subcircuit for advanced training when the host has not read the plurality of subsampled signals from the training register at one time, until the host is enabled to read the plurality of subsampled signals from the training register at one time to obtain the trained write data delay control circuit; the initial subcircuit for advanced training being the initial subcircuit corresponding to the subsample signal that has not been read; and the initial adjustment information of the initial subcircuit for advanced training being adjustment information used during the single-circuit delay adjustment training to obtain the initial subcircuit.

Specifically, the computer device may use the initial subcircuit corresponding to an unread subsample signal as the initial subcircuit for advanced training. In addition, the computer device may use, as the initial adjustment information of the initial subcircuit for advanced training, the adjustment information used during the single-circuit delay adjustment training to obtain the initial subcircuit. The computer device may read each subsampled signal from the training register of the memory by using the host. If the host has not read the plurality of subsampled signals from the training register at one time, it means that the sampling edges of the sampling signals aligned with the subsample signals are not the same sampling edge. In this case, the computer device may continuously perform the delay adjustment training on the initial subcircuit for advanced training based on the initial adjustment information of the initial subcircuit for advanced training, until the host reads the plurality of subsampled signals from the training register at one time. It may be understood that the host is enabled to read the plurality of subsampled signals from the training register at one time, which means that the sampling edges of the sampling signals aligned with the subsample signals are the same sampling edge. In this case, the trained write data delay control circuit may be determined based on the plurality of trained target subcircuits obtained from the continuous training.

In the foregoing embodiments, the host has not read the plurality of subsampled signals from the training register at one time, which means that the sampling edges of the sampling signals aligned with the subsample signals are not the same sampling edge. In this case, the delay adjustment training is continuously performed on the initial subcircuit for advanced training based on the initial adjustment information of the initial subcircuit for advanced training, until the host reads the plurality of subsampled signals from the training register at one time, so that the subsample signals are aligned with the same sampling edge of the sampling signals, thereby further improving the training effect of the write data delay control circuit.

In an embodiment, the continuously performing the delay adjustment training on an initial subcircuit for advanced training based on initial adjustment information of the initial subcircuit for advanced training, until the host is enabled to read the plurality of subsampled signals from the training register at one time to obtain the trained write data delay control circuit includes: gradually adjusting, based on the initial adjustment information of the initial subcircuit for advanced training, the initial subcircuit for advanced training for the purpose of increasing or decreasing a delay of a target subsample signal, until the host is enabled to read the plurality of subsampled signals from the training register at one time to obtain the trained write data delay control circuit, the target subsample signal being a subsample signal corresponding to the initial subcircuit for advanced training.

Specifically, the computer device may use the subsample signal corresponding to the initial subcircuit for advanced training as the target subsample signal. Then the computer device may gradually adjust, based on the initial adjustment information of the initial subcircuit for advanced training, the initial subcircuit for advanced training for the purpose of increasing or decreasing the delay of a target subsample signal, until the host is enabled to read the plurality of subsampled signals from the training register at one time to obtain the trained write data delay control circuit.

It may be understood that the initial subcircuit for advanced training is adjusted based on the initial adjustment information, so that the target subsample signal may be moved for the purpose of increasing or decreasing the delay based on the entire clock period.

For example, the computer device may first adjust, based on the initial adjustment information of the initial subcircuit for advanced training, the initial subcircuit for advanced training for the purpose of increasing the delay of the target subsample signal by one clock period. If the host still has not read the plurality of subsampled signals from the training register at one time, the target subsample signal is restored to a state before the delay adjustment, and then the initial subcircuit for advanced training is adjusted for the purpose of decreasing the delay of the target subsample signal by one clock period. If the host still has not read the plurality of subsampled signals from the training register at one time, the initial subcircuit for advanced training is continuously adjusted for the purpose of increasing the delay of the target subsample signal by two clock periods. If the host still has not read the plurality of subsampled signals from the training register at one time, the initial subcircuit for advanced training is continuously adjusted for the purpose of decreasing the delay of the target subsample signal by two clock periods, and so on. The initial subcircuit for advanced training is gradually adjusted until the host is enabled to read the plurality of subsampled signals from the training register at one time, to obtain the trained write data delay control circuit.

In the foregoing embodiments, when the host has not read the plurality of subsampled signals from the training register at one time, the initial subcircuit for advanced training is gradually adjusted based on the initial adjustment information of the initial subcircuit for advanced training for the purpose of increasing or decreasing the delay of the target subsample signal, until the host is enabled to read the plurality of subsampled signals from the training register at one time, so that the subsample signals are aligned with the same sampling edge of the sampling signals, thereby further improving the training effect of the write data delay control circuit.

In an embodiment, the foregoing write data signal delay control method further includes: using each initial subcircuit as each target subcircuit to obtain the trained write data delay control circuit when the host is enabled to read the plurality of subsampled signals from the training register at one time.

Specifically, the computer device may read each subsampled signal from the training register of the memory by using the host. If the host is enabled to read the plurality of subsampled signals from the training register at one time, it means that the sampling edges of the sampling signals aligned with the subsample signals are the same sampling edge. In this case, each initial subcircuit is used as each target subcircuit, to obtain the trained write data delay control circuit.

In the foregoing embodiments, if the host is enabled to read the plurality of subsampled signals from the training register at one time, it means that the sampling edges of the sampling signals aligned with the subsample signals are the same sampling edge. In this case, each initial subcircuit may be directly used as each target subcircuit, to obtain the trained write data delay control circuit. In this way, the training efficiency of the write data delay control circuit can be enhanced while ensuring the training effect of the write data delay control circuit.

In an embodiment, the subcircuit includes write data delay units that are successively connected, each of the write data delay units being succeeded by a tap interface, the tap interface supporting exporting of a signal from the subcircuit, and the initial subcircuit being a circuit for which a target tap interface has been determined; and the performing, for each subcircuit in the write data delay control circuit, single-circuit delay adjustment training on the subcircuit based on the subsample signal corresponding to the subcircuit, to obtain a trained initial subcircuit includes: performing, for each subcircuit in the write data delay control circuit, single-circuit delay adjustment training on the subcircuit based on the subsample signal corresponding to the subcircuit, to determine delay adjustment information for the subcircuit; and determining a target tap interface from the subcircuit based on the delay adjustment information, a target write data delay unit before the target tap interface being configured to perform signal offset adjustment on the subsample signal corresponding to the subcircuit through delay processing, to obtain a signal aligned with the sampling edge of the sampling signal.

The write data delay unit is a smallest unit in the subcircuit for performing delay control processing on the write data signal. It may be understood that a larger quantity of write data delay units that perform delay control processing on the write data signal lead to a longer delay of the write data signal, and vice versa. The tap interface is an interface arranged after each write data delay unit in the subcircuit, and the tap interface supports exporting of a signal from the subcircuit. It may be understood that the write data signal may be extracted from any tap interface when being transmitted through the subcircuit, so that the write data signal is exported from the subcircuit. It may be understood that the write data delay unit in the subcircuit before the tap interface responsible for exporting the write data signal performs the delay control processing on the write data signal, and the write data delay unit after the tap interface does not perform delay control processing on the write data signal. The delay adjustment information is information for adjusting the subcircuit. It may be understood that the adjustment to the subcircuit refers to adjustment to a quantity of write data delay units in the subcircuit through which the write data signal is transmitted, to increase or decrease the delay of the write data signal. The target tap interface is a tap interface configured to export the write data signal from the subcircuit. The target write data delay unit is all the write data delay units located before the target tap interface in the subcircuit.

Specifically, the computer device may perform, for each subcircuit in the write data delay control circuit, the delay adjustment training on the subcircuit based on the subsample signal corresponding to the subcircuit. After the training, the computer device may obtain the delay adjustment information for the subcircuit on the host. The computer device may determine the target tap interface from each tap interface in the subcircuit based on the delay adjustment information. It may be understood that the computer device may perform delay processing on the subsample signal corresponding to the subcircuit through the target delay unit located before the target tap interface, to adjust the offset between the subsample signal corresponding to the subcircuit and the sampling edge of the sampling signal, so that the subsample signal corresponding to the subcircuit is aligned with the sampling edge of the sampling signal in the memory again.

In an embodiment, the computer device performs delay adjustment training on the subcircuit based on the subsample signal corresponding to the subcircuit. To be specific, the computer device may adjust the subcircuit on the host for the purpose of increasing the delay of the subsample signal corresponding to the subcircuit, and adjust the subcircuit on the host for the purpose of decreasing the delay of the subsample signal corresponding to the subcircuit, to complete the delay adjustment training of the subcircuit to obtain the delay adjustment information.

In an embodiment, the computer device may increase the delay of the subsample signal corresponding to the subcircuit by increasing the quantity of write data delay units through which the subsample signal corresponding to the subcircuit is transmitted, and decrease the delay of the subsample signal corresponding to the subcircuit by decreasing the quantity of write data delay units through which the subsample signal corresponding to the subcircuit is transmitted.

In the foregoing embodiments, the delay adjustment information of each subcircuit may be determined through the single-circuit delay adjustment training on each corresponding subcircuit based on the subsample signal corresponding to the subcircuit. Therefore, the target tap interface may be determined from each subcircuit based on the delay adjustment information corresponding to each subcircuit, to obtain the initial subcircuit, which improves the training effect of the initial subcircuit.

In an embodiment, the performing, for each subcircuit in the write data delay control circuit, single-circuit delay adjustment training on the subcircuit based on the subsample signal corresponding to the subcircuit, to determine delay adjustment information for the subcircuit includes: adjusting, for each subcircuit in the write data delay control circuit in a first state in which the memory has sampled the subsample signal corresponding to the subcircuit based on the sampling signal, the subcircuit for the purpose of increasing a delay of the subsample signal corresponding to the subcircuit, to obtain first adjustment information for the subcircuit until a second state in which the memory has not sampled the subsample signal corresponding to the subcircuit based on the sampling signal occurs; restoring the second state to the first state, and adjusting the subcircuit for the purpose of decreasing the delay of the subsample signal corresponding to the subcircuit, to obtain second adjustment information for the subcircuit until the second state in which the memory has not sampled the subsample signal corresponding to the subcircuit based on the sampling signal occurs; and determining the delay adjustment information for the subcircuit based on the first adjustment information and the second adjustment information.

The first state is a state in which the memory has sampled the subsample signal corresponding to the subcircuit based on the sampling signal. The second state is a state in which the memory has not sampled the subsample signal corresponding to the subcircuit based on the sampling signal. The first adjustment information is adjustment information recorded when the memory has not sampled the subsample signal corresponding to the subcircuit based on the sampling signal after the memory has sampled the subsample signal corresponding to the subcircuit based on the sampling signal, that is, when the subsample signal corresponding to the subcircuit is in a critical state, in the process of increasing the delay of the subsample signal corresponding to the subcircuit. The second adjustment information is adjustment information recorded when the memory has not sampled the subsample signal corresponding to the subcircuit based on the sampling signal after the memory has sampled the subsample signal corresponding to the subcircuit based on the sampling signal, that is, when the subsample signal corresponding to the subcircuit is in a critical state, in the process of decreasing the delay of the subsample signal corresponding to the subcircuit.

Specifically, for each subcircuit in the write data delay control circuit, the computer device may transmit the subsample signal corresponding to the subcircuit to the memory by using the host, and may sample the subsample signal corresponding to the subcircuit based on the sampling signal of the memory. In the first state in which the memory has sampled the subsample signal corresponding to the subcircuit based on the sampling signal, the computer device may adjust the subcircuit for the purpose of increasing the delay of the subsample signal corresponding to the subcircuit. To be specific, the quantity of write data delay units through which the subsample signal corresponding to the subcircuit is transmitted is gradually increased, and the first adjustment information for the subcircuit is recorded until the second state in which the memory has not sampled the subsample signal corresponding to the subcircuit based on the sampling signal occurs. The second state is restored to the first state. To be specific, the second state in which the memory has not sampled the subsample signal corresponding to the subcircuit based on the sampling signal is restored to the first state in which the memory has sampled the subsample signal corresponding to the subcircuit based on the sampling signal at the beginning of training, and the subcircuit is adjusted for the purpose of decreasing the delay of the subsample signal corresponding to the subcircuit. To be specific, the quantity of write data delay units through which the subsample signal corresponding to the subcircuit is transmitted is gradually reduced, and the second adjustment information for the subcircuit is recorded until the second state in which the memory has not sampled the subsample signal corresponding to the subcircuit based on the sampling signal occurs again. Then the computer device may determine the delay adjustment information for the subcircuit based on the recorded first adjustment information and the recorded second adjustment information.

In an embodiment, the computer device gradually increases or decreases the quantity of write data delay units through which the subsample signal corresponding to the subcircuit is transmitted. To be specific, the quantity of write data delay units through which the subsample signal corresponding to the subcircuit is transmitted may be gradually increased or reduced, and the quantity of write data delay units increased or decreased at each step may be at least one. For example, one write data delay unit is increased or decreased in one step, or two write data delay units may be increased or decreased in one step, and three write data delay units may also be increased or decreased in one step.

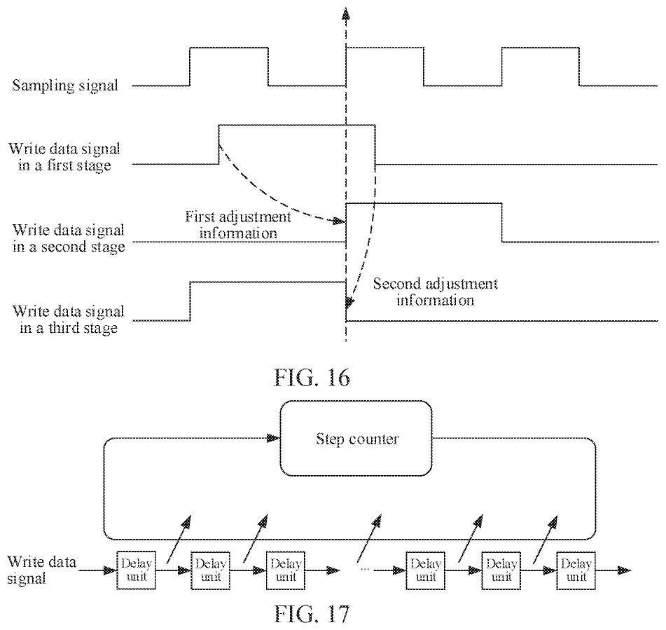

In an embodiment, as shown in FIG. 16, the computer device may sample the subsample signal corresponding to the subcircuit based on the sampling signal of the memory. In a first stage of the delay adjustment training, in the first state in which the memory has sampled the subsample signal corresponding to the subcircuit based on the sampling signal, the computer device may adjust the write data delay control circuit on the host for the purpose of increasing the delay of the subsample signal corresponding to the subcircuit, and immediately record the first adjustment information for the subcircuit until the second state in which the memory has not sampled the subsample signal corresponding to the subcircuit based on the sampling signal occurs, that is, a second stage of the delay adjustment training is reached. Then the computer device may restore the second state to the first state, that is, restore the second state to the first stage of the delay adjustment training, adjust the subcircuit for the purpose of decreasing the delay of the subsample signal corresponding to the subcircuit, and immediately record the second adjustment information for the subcircuit until the second state in which the memory has not sampled the subsample signal corresponding to the subcircuit based on the sampling signal occurs again, that is, a third stage of the delay adjustment training is reached.

In the foregoing embodiments, the memory may sample the subsample signal corresponding to the subcircuit based on the sampling signal before the delay adjustment is performed, which indicates that the sampling edge of the sampling signal is still located within a data window of the subsample signal. In this case, the subcircuit is adjusted for the purpose of increasing the delay of the subsample signal corresponding to the subcircuit, which may increase the delay of the subsample signal. Once a case that the subsample signal has not been sampled occurs in the process of increasing the delay, the first adjustment information indicating one side of the critical state in the data window may be immediately recorded. After the subsample signal corresponding to the subcircuit is reset, the delay of the subsample signal may be decreased by adjusting the subcircuit for the purpose of decreasing the delay of the subsample signal corresponding to the subcircuit. Once a case that the subsample signal has not been sampled occurs in the process of decreasing the delay, the second adjustment information indicating an other side of the critical state in the data window may be immediately recorded. Since a clock period may be exactly determined based on the first adjustment information and the second adjustment information, the delay adjustment information for the subcircuit may be accurately determined based on the first adjustment information and the second adjustment information.

In an embodiment, the subcircuit includes a first constituent circuit and a second constituent circuit. The second constituent circuit is connected after the first constituent circuit. The first constituent circuit and the second constituent circuit respectively include the write data delay units that are successively connected. The first adjustment information includes a first quantity of write data delay units in the second constituent circuit through which the subsample signal corresponding to the subcircuit has been transmitted. The adjusting, for each subcircuit in the write data delay control circuit in a first state in which the memory has sampled the subsample signal corresponding to the subcircuit based on the sampling signal, the subcircuit for the purpose of increasing a delay of the subsample signal corresponding to the subcircuit, to obtain first adjustment information for the subcircuit until a second state in which the memory has not sampled the subsample signal corresponding to the subcircuit based on the sampling signal occurs includes: controlling the subsample signal corresponding to the subcircuit to successively pass through each write data delay unit in the first constituent circuit to perform initial delay control processing, to obtain the subsample signal corresponding to the subcircuit after initial control; and continuously controlling, in a first state in which the memory has sampled the subsample signal corresponding to the subcircuit based on the sampling signal, the subsample signal corresponding to the subcircuit after the initial control to be transmitted through the write data delay units in the second constituent circuit one by one for the purpose of increasing the delay of the subsample signal corresponding to the subcircuit after the initial control, and recording the first quantity of write data delay units in the second constituent circuit through which the subsample signal corresponding to the subcircuit has been transmitted until the second state in which the memory has not sampled the subsample signal corresponding to the subcircuit from a corresponding tap interface of the second constituent circuit based on the sampling signal occurs.

The first constituent circuit and the second constituent circuit are respectively constituent circuits in the subcircuit.

Specifically, for each subcircuit in the write data delay control circuit, the computer device may control, by using the host, the subsample signal corresponding to the subcircuit to successively pass through each write data delay unit in the first constituent circuit to perform initial delay control processing on the subsample signal corresponding to the subcircuit, to obtain the subsample signal corresponding to the subcircuit after initial control. The computer device may sample the subsample signal corresponding to the subcircuit after the initial control based on the sampling signal of the memory. In the first state in which the memory has sampled the subsample signal corresponding to the subcircuit after the initial control based on the sampling signal, the computer device may continuously control the subsample signal corresponding to the subcircuit after the initial control to be transmitted through the write data delay units in the second constituent circuit one by one for the purpose of increasing the delay of the subsample signal corresponding to the subcircuit after the initial control, and record a first quantity of write data delay units in the second constituent circuit through which the subsample signal corresponding to the subcircuit has been transmitted until the second state in which the memory has not sampled the subsample signal corresponding to the subcircuit from the corresponding tap interface of the second constituent circuit based on the sampling signal occurs.

In the foregoing embodiments, the first constituent circuit first performs the initial delay control processing on the subsample signal corresponding to the subcircuit, to obtain the subsample signal corresponding to the subcircuit after the initial control. In this case, the subsample signal corresponding to the subcircuit after the initial control may not be aligned with the sampling edge of the sampling signal. In the first state in which the subsample signal corresponding to the subcircuit after the initial control has been sampled, the subsample signal corresponding to the subcircuit after the initial control is continuously controlled to be transmitted through the write data delay units in the second constituent circuit one by one for the purpose of increasing the delay of the subsample signal corresponding to the subcircuit after the initial control, and the first quantity of write data delay units in the second constituent circuit through which the subsample signal corresponding to the subcircuit has been transmitted is immediately recorded until the second state in which the memory has not sampled the subsample signal corresponding to the subcircuit from the corresponding tap interface of the second constituent circuit based on the sampling signal occurs. In this way, the first adjustment information accurately representing one side of the critical state in the data window of the subsample signal corresponding to the subcircuit may be recorded, thereby further improving accuracy of the obtained delay adjustment information.

In an embodiment, the second adjustment information includes a second quantity of write data delay units through which the subsample signal corresponding to the subcircuit has not been transmitted. The restoring the second state to the first state, and adjusting the subcircuit for the purpose of decreasing the delay of the subsample signal corresponding to the subcircuit, to obtain second adjustment information for the subcircuit until the second state in which the memory has not sampled the subsample signal corresponding to the subcircuit based on the sampling signal occurs includes: restoring the second state to the first state, controlling the subsample signal corresponding to the subcircuit after the initial control to be transmitted through the write data delay units in the first constituent circuit one by one for the purpose of decreasing the delay of the subsample signal corresponding to the subcircuit after the initial control, and recording the second quantity of write data delay units through which the subsample signal corresponding to the subcircuit has not been transmitted until the second state in which the memory has not sampled the subsample signal corresponding to the subcircuit from the corresponding tap interface of the first constituent circuit based on the sampling signal occurs.

Specifically, the computer device may restore the second state to the first state, that is, restore the second state in which the memory has not sampled the subsample signal corresponding to the subcircuit after the initial control based on the sampling signal, to the first state in which the memory has sampled the subsample signal corresponding to the subcircuit after the initial control based on the sampling signal at the beginning of the training. Then the computer device may control the subsample signal corresponding to the subcircuit after the initial control to be transmitted through the write data delay units in the first constituent circuit one by one for the purpose of decreasing the delay of the subsample signal corresponding to the subcircuit after the initial control, and the computer device may record the second quantity of write data delay units through which the subsample signal corresponding to the subcircuit has not been transmitted until the second state in which the memory has not sampled the subsample signal corresponding to the subcircuit from the corresponding tap interface of the first constituent circuit based on the sampling signal occurs.

In the foregoing embodiments, the subsample signal corresponding to the subcircuit after the initial control is controlled to be transmitted through the write data delay units in the first constituent circuit one by one for the purpose of decreasing the delay of the subsample signal corresponding to the subcircuit after the initial control, and the second quantity of write data delay units through which the subsample signal corresponding to the subcircuit has not been transmitted is immediately recorded until the second state in which the memory has not sampled the subsample signal corresponding to the subcircuit from the corresponding tap interface of the first constituent circuit based on the sampling signal occurs. In this way, the second adjustment information accurately representing an other side of the critical state in the data window of the subsample signal corresponding to the subcircuit may be recorded, thereby further improving the accuracy of the obtained delay adjustment information.

In an embodiment, the determining the delay adjustment information for the subcircuit based on the first adjustment information and the second adjustment information includes: determining delay adjustment information for the subcircuit based on an average of the first quantity and the second quantity.

Specifically, the computer device may calculate the average of the first quantity and the second quantity, and calculate the delay adjustment information for the subcircuit based on the average of the first quantity and the second quantity.

In an embodiment, the computer device may directly use the calculated average of the first quantity and the second quantity as the delay adjustment information for the subcircuit.

In the foregoing embodiments, the delay adjustment information is determined by using the average of the first quantity and the second quantity, so as to further improve the accuracy of the delay adjustment information.

In an embodiment, as shown in FIG. 17, each subcircuit of the write data delay control circuit includes a step counter. The step counter may be configured to record a first quantity of write data delay units in the second constituent circuit through which the write data signal has been transmitted, and record a second quantity of write data delay units through which the write data signal has not been transmitted.

In an embodiment, before the adjusting, for each subcircuit in the write data delay control circuit in a first state in which the memory has sampled the subsample signal corresponding to the subcircuit based on the sampling signal, the subcircuit for the purpose of increasing a delay of the subsample signal corresponding to the subcircuit, the method further includes: performing, in the second state in which the memory has not sampled the subsample signal corresponding to the subcircuit based on the sampling signal, frequency reduction adjustment processing on a current operating frequency of the memory, to obtain a reduced target operating frequency, the target operating frequency being an operating frequency at which the memory samples the subsample signal corresponding to the subcircuit based on the sampling signal; and sampling the subsample signal corresponding to the subcircuit based on a sampling signal in the memory operating at the target operating frequency, so that the memory samples the subsample signal corresponding to the subcircuit based on the sampling signal.

The current operating frequency is a current operating frequency of the memory, that is, an operating frequency of the memory when the memory has not sampled the subsample signal corresponding to the subcircuit based on the sampling signal. The target operating frequency is a frequency obtained after the frequency reduction adjustment processing is performed on the current operating frequency.

Specifically, for each subcircuit in the write data delay control circuit, the computer device may transmit the subsample signal corresponding to the subcircuit to the memory by using the host, and sample the subsample signal corresponding to the subcircuit based on the sampling signal of the memory. The second state in which the memory has not sampled the subsample signal corresponding to the subcircuit based on the sampling signal indicates that the current operating frequency of the memory is excessively high, resulting in a short period of time for which the subsample signal corresponding to the subcircuit remains high. As a result, the memory cannot sample the subsample signal corresponding to the subcircuit based on the sampling signal. In this case, the computer device may perform frequency reduction adjustment processing on the current operating frequency of the memory, to obtain the reduced target operating frequency. It may be understood that the operating frequency of the memory is reduced, so that the duration for which the subsample signal corresponding to the subcircuit remains high may be prolonged, and the memory operating at the target operating frequency can smoothly sample the subsample signal corresponding to the subcircuit. Then the computer device may sample the subsample signal corresponding to the subcircuit based on the memory operating at the target operating frequency, so that the memory samples the subsample signal corresponding to the subcircuit. Afterward, in the first state in which the memory has sampled the subsample signal corresponding to the subcircuit based on the sampling signal, the step of adjusting the subcircuit for the purpose of increasing the delay of the subsample signal corresponding to the subcircuit and the subsequent steps thereof are performed.

In the foregoing embodiments, after the memory receives the subsample signal corresponding to the subcircuit transmitted by the host, if the memory has not sampled the subsample signal corresponding to the subcircuit based on the sampling signal, it means that the sampling edge of the sampling signal has drifted out of the data window in which the subsample signal corresponding to the subcircuit is located. In this case, the current operating frequency of the memory is reduced to the target operating frequency, so that the memory operating at the target operating frequency may prolong the duration for which the subsample signal corresponding to the subcircuit remains high, and then the memory may sample the subsample signal corresponding to the subcircuit based on the sampling signal, which increases a success rate of the delay adjustment training.

In an embodiment, after the performing delay adjustment training on a write data delay control circuit arranged on the host based on the sample write data signal, to obtain a trained write data delay control circuit, the foregoing write data signal delay control method further includes: periodically triggering through the timer to perform, through hardware control, a step of configuring a register mode of the register circuit in the memory by using the host to obtain the training register for caching data, to trigger re-performing of the delay adjustment training.

Specifically, the timer is deployed in the computer device. The computer device may periodically trigger through the timer to perform, through the hardware control, the step of configuring the register mode of the register circuit in the memory by using the host to obtain the training register for caching data, to trigger re-performing of the delay adjustment training. It may be understood that the computer device may perform timing by using the timer, and the re-performing of the delay adjustment training through hardware control is triggered once every preset interval.

For example, the computer device may perform timing by using the timer, and the re-performing of the delay adjustment training through hardware control is triggered once every 24 hours.

In the foregoing embodiments, periodic retraining of the write data delay control circuit through hardware control is periodically triggered by using the timer, so as to ensure that no offset exists between the write data signal and the sampling edge of the sampling signal during operation of the computer device, further improving operation stability of the memory.

In an embodiment, after the performing delay adjustment training on a write data delay control circuit arranged on the host based on the sample write data signal, to obtain a trained write data delay control circuit, the method further includes: monitoring a system operating state of a high-bandwidth memory system, the high-bandwidth memory system including the host and the memory; and re-performing, through software control when the system operating state is an unbusy state, the operation of configuring the operating mode of the register circuit in the memory by using the host, to obtain the training register for caching data, to trigger re-performing of the delay adjustment training.

Specifically, the high-bandwidth memory system is deployed in the computer device, and the computer device may monitor the operating state of the high-bandwidth memory system. If it is detected that the system operating state of the high-bandwidth memory system is the unbusy state, the computer device may re-perform, through software control, the operation of configuring the operating mode of the register circuit in the memory by using the host, to obtain the training register for caching data, to trigger the re-performing of the delay adjustment training. If it is detected that the system operating state of the high-bandwidth memory system is a busy state, the computer device may temporarily not perform the delay adjustment training through software control, and then perform the delay adjustment training when it is detected that the system operating state of the high-bandwidth memory system is the unbusy state next time.

In the foregoing embodiments, the write data delay control circuit may be retrained through software control when the high-bandwidth memory system is not busy, so as to further ensure that no offset exists between the write data signal and the sampling edge of the sampling signal during operation of the computer device, further improving operation stability of the memory. In addition, the write data delay control circuit is retrained when the high-bandwidth memory system is not busy, which may also ensure operating efficiency of the entire high-bandwidth memory system.

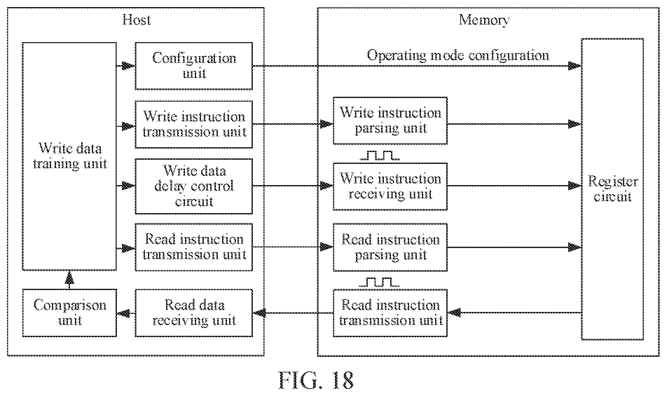

In an embodiment, as shown in FIG. 18, a high-bandwidth memory system runs in a computer device. The high-bandwidth memory system includes a host and a memory. The host includes a configuration unit, a write instruction transmission unit, a write data delay control circuit, a read instruction transmission unit, a read data receiving unit, a comparison unit, and a write data training unit. The memory includes a write instruction parsing unit, a write instruction receiving unit, a read instruction parsing unit, a read instruction transmission unit, and a register circuit. The computer device configures an operating mode of the register circuit in the memory through the configuration unit, to configure a memory circuit to operate in a read-write mode to obtain a training register. The host may transmit a write instruction to the memory, and the memory may parse the write instruction through the write instruction parsing unit. After the write instruction is parsed, the host may transmit a sample write data signal to the memory, and the memory may receive the sample write data signal through the write instruction receiving unit. Then the memory may sample the sample write data signal based on the sampling signal, and write a sampled write data signal obtained from the sampling to the training register. The host may transmit a read instruction to the memory by using the read instruction transmission unit, and the memory may parse the read instruction by using the read instruction parsing unit. After the read instruction is parsed, the memory may read the sampled write data signal from the training register, and transmit the sampled write data signal to the host by using the read instruction transmission unit. The host may receive the sampled write data signal by using the read data receiving unit, and forward the sampled write data signal to the comparison unit. The host may compare the sampled write data signal with the sample write data signal by using the comparison unit. When the sampled write data signal read by the host from the training register is inconsistent with the sample write data signal, the computer device may perform delay adjustment training on the write data delay control circuit arranged on the host based on the sample write data signal, to obtain a trained write data delay control circuit. Then in an actual application scenario, the computer device may perform signal offset adjustment on an inputted write data signal by using the trained write data delay control circuit, obtain a target write data signal aligned with the sampling edge of the sampling signal, and write the target write data signal to the memory.

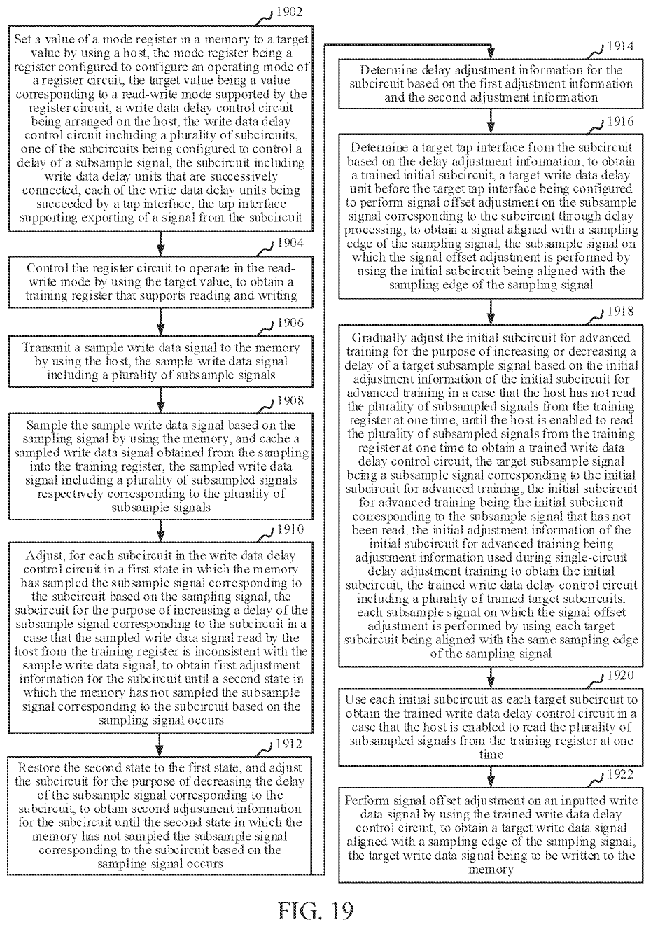

As shown in FIG. 19, in an embodiment, a write data signal delay control method is provided. The method may be applied to a computer device. The computer device may be a terminal or a server. The method may be performed by the terminal or the server independently, or may be implemented through interaction between the terminal and the server. The method specifically includes the following steps:

Step 1902: Set a value of a mode register in a memory to a target value by using a host, the mode register being a register configured to configure an operating mode of a register circuit, the target value being a value corresponding to a read-write mode supported by the register circuit, a write data delay control circuit being arranged on the host, the write data delay control circuit including a plurality of subcircuits, one of the subcircuits being configured to control a delay of one subsample signal, the subcircuit including write data delay units that are successively connected, each of the write data delay units being succeeded by a tap interface, the tap interface supporting exporting of a signal from the subcircuit.

Step 1904: Control, by using the target value, the register circuit to operate in the read-write mode, to obtain a training register that supports reading and writing.

Step 1906: Transmit a sample write data signal to the memory by using the host, the sample write data signal including a plurality of subsample signals.

Step 1908: Sample the sample write data signal based on a sampling signal by using the memory, and cache a sampled write data signal obtained from the sampling into the training register, the sampled write data signal including a plurality of subsampled signals respectively corresponding to the plurality of subsample signals.

Step 1910: Adjust, for each subcircuit in the write data delay control circuit in a first state in which the memory has sampled the subsample signal corresponding to the subcircuit based on the sampling signal, the subcircuit for the purpose of increasing a delay of the subsample signal corresponding to the subcircuit when the sampled write data signal read by the host from the training register is inconsistent with the sample write data signal, to obtain first adjustment information for the subcircuit until a second state in which the memory has not sampled the subsample signal corresponding to the subcircuit based on the sampling signal occurs.

Step 1912: Restore the second state to the first state, and adjust the subcircuit for the purpose of decreasing the delay of the subsample signal corresponding to the subcircuit, to obtain second adjustment information for the subcircuit until the second state in which the memory has not sampled the subsample signal corresponding to the subcircuit based on the sampling signal occurs.

Step 1914: Determine delay adjustment information for the subcircuit based on the first adjustment information and the second adjustment information.

Step 1916: Determine a target tap interface from the subcircuit based on the delay adjustment information, to obtain a trained initial subcircuit, a target write data delay unit before the target tap interface being configured to perform signal offset adjustment on the subsample signal corresponding to the subcircuit through delay processing, to obtain a signal aligned with a sampling edge of the sampling signal, and the subsample signal on which the signal offset adjustment is performed by using the initial subcircuit being aligned with the sampling edge of the sampling signal.

Step 1918: Gradually adjust, based on initial adjustment information of the initial subcircuit for advanced training, the initial subcircuit for advanced training for the purpose of increasing or decreasing a delay of a target subsample signal when the host has not read the plurality of subsampled signals from the training register at one time, until the host is enabled to read the plurality of subsampled signals from the training register at one time to obtain a trained write data delay control circuit, the target subsample signal being a subsample signal corresponding to the initial subcircuit for advanced training, the initial subcircuit for advanced training being the initial subcircuit corresponding to the subsample signal that has not been read, the initial adjustment information of the initial subcircuit for advanced training being adjustment information used during the single-circuit delay adjustment training to obtain the initial subcircuit, the trained write data delay control circuit including a plurality of trained target subcircuits, each subsample signal on which the signal offset adjustment is performed by using each of the target subcircuits being aligned with the same sampling edge of the sampling signal.

Step 1920: Use each initial subcircuit as each target subcircuit to obtain the trained write data delay control circuit when the host is enabled to read the plurality of subsampled signals from the training register at one time.

Step 1922: Perform signal offset adjustment on an inputted write data signal by using the trained write data delay control circuit, to obtain a target write data signal aligned with the sampling edge of the sampling signal, the target write data signal being to be written to the memory.

This application further provides an application scenario. The foregoing write data signal delay control method is applied to the application scenario. Specifically, a high-bandwidth memory system is deployed in a computer device. The high-bandwidth memory system includes a host and a DRAM. The write data signal delay control method may be applied to a scenario for write data signal delay control when the high-bandwidth memory system is in an operating state. The computer device may set a value of a mode register in the DRAM to a target value by using the host. The mode register is a register configured to configure an operating mode of a register circuit. The target value is a value corresponding to a read-write mode supported by the register circuit. A write data delay control circuit is arranged on the host. The write data delay control circuit includes a plurality of subcircuits. One of the subcircuits is configured to control a delay of one subsample signal. The subcircuit includes write data delay units that are successively connected. Each of the write data delay units is succeeded by a tap interface. The tap interface supports exporting of a signal from the subcircuit. The register circuit is controlled, by using the target value, to operate in the read-write mode, to obtain a training register that supports reading and writing. A sample write data signal is transmitted to the DRAM by using the host. The sample write data signal includes a plurality of subsample signals.

The computer device may be configured to sample the sample write data signal based on a sampling signal by using the DRAM, and cache a sampled write data signal obtained from the sampling into the training register. The sampled write data signal includes a plurality of subsampled signals respectively corresponding to the plurality of subsample signals. When the sampled write data signal read by the host from the training register is inconsistent with the sample write data signal, for each subcircuit in the write data delay control circuit, in a first state in which the DRAM has sampled the subsample signal corresponding to the subcircuit based on the sampling signal, the subcircuit is adjusted for the purpose of increasing a delay of the subsample signal corresponding to the subcircuit, to obtain first adjustment information for the subcircuit until a second state in which the DRAM has not sampled the subsample signal corresponding to the subcircuit based on the sampling signal occurs. The second state is restored to the first state, and the subcircuit is adjusted for the purpose of decreasing the delay of the subsample signal corresponding to the subcircuit, to obtain second adjustment information for the subcircuit until the second state in which the DRAM has not sampled the subsample signal corresponding to the subcircuit based on the sampling signal occurs. Delay adjustment information for the subcircuit is determined based on the first adjustment information and the second adjustment information. A target tap interface is determined from the subcircuit based on the delay adjustment information, to obtain a trained initial subcircuit. A target write data delay unit before the target tap interface is configured to perform signal offset adjustment on the subsample signal corresponding to the subcircuit through delay processing, to obtain a signal aligned with a sampling edge of the sampling signal. The subsample signal on which the signal offset adjustment is performed by using the initial subcircuit is aligned with the sampling edge of the sampling signal.

When the host has not read the plurality of subsampled signals from the training register at one time, the computer device may gradually adjust, based on initial adjustment information of the initial subcircuit for advanced training, the initial subcircuit for advanced training for the purpose of increasing or decreasing a delay of a target subsample signal, until the host is enabled to read the plurality of subsampled signals from the training register at one time to obtain a trained write data delay control circuit. The target subsample signal is a subsample signal corresponding to the initial subcircuit for advanced training. The initial subcircuit for advanced training is the initial subcircuit corresponding to the subsample signal that has not been read. The initial adjustment information of the initial subcircuit for advanced training is adjustment information used during the single-circuit delay adjustment training to obtain the initial subcircuit. The trained write data delay control circuit includes a plurality of trained target subcircuits. Each subsample signal on which the signal offset adjustment is performed by using each of the target subcircuits is aligned with the same sampling edge of the sampling signal. Each initial subcircuit is used as each target subcircuit to obtain the trained write data delay control circuit when the host is enabled to read the plurality of subsampled signals from the training register at one time.

The computer device may perform signal offset adjustment on an inputted write data signal by using the trained write data delay control circuit, to obtain a target write data signal aligned with the sampling edge of the sampling signal. The target write data signal is to be written to the DRAM.

This application further provides an application scenario. The foregoing write data signal delay control method is applied to the application scenario. Specifically, a high-bandwidth memory system is deployed in a computer device. The high-bandwidth memory system includes a host and a memory. The write data signal delay control method may be applied to a scenario for write data signal delay control when the high-bandwidth memory system is in a non-operating state. Through the write data signal delay control method in this application, delay adjustment training is performed on the write data delay control circuit in the high-bandwidth memory system in the non-operating state, which ensures correctness of data written to the memory by the high-bandwidth memory system in the subsequent operating state, thereby improving operating stability of the memory.

It is to be understood that, although the steps are displayed sequentially in the flowcharts of the embodiments, these steps are not necessarily performed sequentially according to the sequence. Unless otherwise explicitly specified in this specification, execution of the steps is not strictly limited, and the steps may be performed in another sequence. Moreover, at least some of the steps in each embodiment may include a plurality of sub-steps or a plurality of stages. The sub-steps or stages are not necessarily performed at the same moment but may be performed at different moments. Execution of the sub-steps or stages is not necessarily sequentially performed, but may be performed alternately with other steps or at least some of sub-steps or stages of other steps.

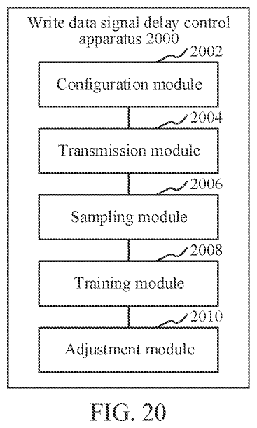

In an embodiment, as shown in FIG. 20, a write data signal delay control apparatus 2000 is provided. The apparatus may adopt a software module, a hardware module, or a combination thereof to become a part of a computer device. The apparatus specifically includes:

a configuration module 2002, configured to configure an operating mode of a register circuit in a memory by using a host, to obtain a training register that supports reading and writing;

a transmission module 2004, configured to transmit a sample write data signal to the memory by using the host;

a sampling module 2006, configured to sample the sample write data signal based on a sampling signal by using the memory, and cache a sampled write data signal obtained from the sampling into the training register;

a training module 2008, configured to perform delay adjustment training on a write data delay control circuit arranged on the host based on the sample write data signal to obtain a trained write data delay control circuit when the sampled write data signal read by the host from the training register is inconsistent with the sample write data signal; and an adjustment module 2010, configured to perform signal offset adjustment on an inputted write data signal by using the trained write data delay control circuit, to obtain a target write data signal aligned with a sampling edge of the sampling signal, the target write data signal being to be written to the memory.

In an embodiment, the configuration module 2002 is configured to set a value of a mode register in the memory to a target value by using the host. The mode register is a register configured to configure an operating mode of a register circuit. The target value is a value corresponding to a read-write mode supported by the register circuit. The register circuit is controlled, by using the target value, to operate in the read-write mode, to obtain the training register that supports reading and writing.

In an embodiment, the sample write data signal includes a plurality of subsample signals. The write data delay control circuit arranged on the host includes a plurality of subcircuits. One of the subcircuits is configured to control a delay of one subsample signal. The training module 2008 is further configured to: perform, for each subcircuit in the write data delay control circuit, single-circuit delay adjustment training on the subcircuit based on the subsample signal corresponding to the subcircuit, to obtain a trained initial subcircuit, the subsample signal on which the signal offset adjustment is performed by using the initial subcircuit being aligned with the sampling edge of the sampling signal; and perform multi-circuit delay adjustment training on each initial subcircuit based on the plurality of subsample signals, to obtain the trained write data delay control circuit. The trained write data delay control circuit includes a plurality of trained target subcircuits. Each subsample signal on which the signal offset adjustment is performed by using each of the target subcircuits is aligned with the same sampling edge of the sampling signal.

In an embodiment, the sampled write data signal includes a plurality of subsampled signals respectively corresponding to the plurality of subsample signals. The training module 2008 is further configured to continuously perform the delay adjustment training on an initial subcircuit for advanced training based on initial adjustment information of the initial subcircuit for advanced training when the host has not read the plurality of subsampled signals from the training register at one time, until the host is enabled to read the plurality of subsampled signals from the training register at one time to obtain the trained write data delay control circuit. The initial subcircuit for advanced training is the initial subcircuit corresponding to the subsample signal that has not been read. The initial adjustment information of the initial subcircuit for advanced training is adjustment information used during the single-circuit delay adjustment training to obtain the initial subcircuit.

In an embodiment, the training module 2008 is further configured to gradually adjust, based on the initial adjustment information of the initial subcircuit for advanced training, the initial subcircuit for advanced training for the purpose of increasing or decreasing a delay of a target subsample signal, until the host is enabled to read the plurality of subsampled signals from the training register at one time to obtain the trained write data delay control circuit, The target subsample signal is the subsample signal corresponding to the initial subcircuit for advanced training.

In an embodiment, the training module 2008 is further configured to use each initial subcircuit as each target subcircuit to obtain the trained write data delay control circuit when the host is enabled to read the plurality of subsampled signals from the training register at one time.

In an embodiment, the subcircuit includes write data delay units that are successively connected, each of the write data delay units is succeeded by a tap interface, the tap interface supports exporting of a signal from the subcircuit, and the initial subcircuit is a circuit for which a target tap interface has been determined. The training module 2008 is further configured to: perform, for each subcircuit in the write data delay control circuit, single-circuit delay adjustment training on the subcircuit based on the subsample signal corresponding to the subcircuit, to determine delay adjustment information for the subcircuit; and determine a target tap interface from the subcircuit based on the delay adjustment information. A target write data delay unit before the target tap interface is configured to perform signal offset adjustment on the subsample signal corresponding to the subcircuit through delay processing, to obtain a signal aligned with the sampling edge of the sampling signal.

In an embodiment, the training module 2008 is further configured to: adjust, for each subcircuit in the write data delay control circuit in a first state in which the memory has sampled the subsample signal corresponding to the subcircuit based on the sampling signal, the subcircuit for the purpose of increasing a delay of the subsample signal corresponding to the subcircuit, to obtain first adjustment information for the subcircuit until a second state in which the memory has not sampled the subsample signal corresponding to the subcircuit based on the sampling signal occurs; restore the second state to the first state, and adjust the subcircuit for the purpose of decreasing the delay of the subsample signal corresponding to the subcircuit, to obtain second adjustment information for the subcircuit until the second state in which the memory has not sampled the subsample signal corresponding to the subcircuit based on the sampling signal occurs; and determine delay adjustment information for the subcircuit based on the first adjustment information and the second adjustment information.

In an embodiment, the subcircuit includes a first constituent circuit and a second constituent circuit. The second constituent circuit is connected after the first constituent circuit. The first constituent circuit and the second constituent circuit respectively include the write data delay units that are successively connected. The first adjustment information includes a first quantity of write data delay units in the second constituent circuit through which the subsample signal corresponding to the subcircuit has been transmitted. The training module 2008 is further configured to: control the subsample signal corresponding to the subcircuit to successively pass through each write data delay unit in the first constituent circuit to perform initial delay control processing, to obtain the subsample signal corresponding to the subcircuit after initial control; and continuously control, in a first state in which the memory has sampled the subsample signal corresponding to the subcircuit based on the sampling signal, the subsample signal corresponding to the subcircuit after the initial control to be transmitted through the write data delay units in the second constituent circuit one by one for the purpose of increasing the delay of the subsample signal corresponding to the subcircuit after the initial control, and record the first quantity of write data delay units in the second constituent circuit through which the subsample signal corresponding to the subcircuit has been transmitted until the second state in which the memory has not sampled the subsample signal corresponding to the subcircuit from a corresponding tap interface of the second constituent circuit based on the sampling signal occurs.

In an embodiment, the second adjustment information includes a second quantity of write data delay units through which the subsample signal corresponding to the subcircuit has not been transmitted. The training module 2008 is further configured to: restore the second state to the first state, control the subsample signal corresponding to the subcircuit after the initial control to be transmitted through the write data delay units in the first constituent circuit one by one for the purpose of decreasing the delay of the subsample signal corresponding to the subcircuit after the initial control, and record the second quantity of write data delay units through which the subsample signal corresponding to the subcircuit has not been transmitted until the second state in which the memory has not sampled the subsample signal corresponding to the subcircuit from the corresponding tap interface of the first constituent circuit based on the sampling signal occurs.

In an embodiment, the training module 2008 is further configured to perform, in the second state in which the memory has not sampled the subsample signal corresponding to the subcircuit based on the sampling signal, frequency reduction adjustment processing on a current operating frequency of the memory, to obtain a reduced target operating frequency, the target operating frequency being an operating frequency at which the memory samples the subsample signal corresponding to the subcircuit based on the sampling signal; and sample the subsample signal corresponding to the subcircuit based on a sampling signal in the memory operating at the target operating frequency, so that the memory samples the subsample signal corresponding to the subcircuit based on the sampling signal.

In an embodiment, the training module 2008 is further configured to monitor a system operating state of a high-bandwidth memory system. The high-bandwidth memory system includes the host and the memory. When the system operating state is an unbusy state, the configuration module 2002 is notified through software control to re-perform the operation of configuring the operating mode of the register circuit in the memory by using the host, to obtain the training register for caching data, to trigger re-performing of the delay adjustment training.

In an embodiment, the transmission module 2004 is further configured to transmit a sample write data signal and a write data selection pulse signal matching the sample write data signal to the memory by using the host. The sampling module 2006 is further configured to: use the write data selection pulse signal received by the memory as the sampling signal; and sample the sample write data signal based on the sampling signal by using the memory, and cache a sampled write data signal obtained from the sampling into the training register.

In an embodiment, the sampling edge of the sampling signal includes a rising edge of the sampling signal. The sampling module 2006 is further configured to sample the sample write data signal based on the rising edge of the sampling signal by using the memory. The adjustment module 2010 is further configured to perform signal offset adjustment on an inputted write data signal by using the trained write data delay control circuit, to obtain a target write data signal aligned with the rising edge of the sampling signal.

In an embodiment, the sampling edge of the sampling signal includes a falling edge of the sampling signal. The sampling module 2006 is further configured to sample the sample write data signal based on the falling edge of the sampling signal by using the memory. The adjustment module 2010 is further configured to perform signal offset adjustment on the inputted write data signal by using the trained write data delay control circuit, to obtain a target write data signal aligned with the falling edge of the sampling signal.

In the foregoing write data signal delay control apparatus, the operating mode of the register circuit in the memory is configured by using the host, to obtain the training register that supports reading and writing. The sample write data signal is transmitted to the memory by using the host. The sample write data signal is sampled based on the sampling signal by using the memory, the sampled write data signal obtained from the sampling is cached in the training register, and the sampled write data signal is compared with the sample write data signal transmitted by the host. If the sampled write data signal read by the host from the training register is inconsistent with the sample write data signal, it means that an offset exists between the sample write data signal transmitted by the host and the sampling signal of the memory. In this case, the delay adjustment training may be performed on the write data delay control circuit arranged on the host based on the sample write data signal, to obtain the trained write data delay control circuit. Then in an actual application process, the signal offset adjustment may be performed on the inputted write data signal by using the trained write data delay control circuit, and the adjusted target write data signal may be transmitted to the memory. In this way, the target write data signal received by the memory may be aligned with the sampling edge of the sampling signal of the memory, so that the memory may correctly sample the write data signal transmitted by the host, thereby ensuring correctness of the data written to the memory, and improving operation stability of the memory.

The modules in the foregoing write data signal delay control apparatus may be implemented in whole or in part by software, hardware, or a combination thereof. The foregoing modules may be built in or independent of a processor of a computer device in a form of hardware, or may be stored in a storage of the computer device in a form of software, so that the processor invokes each of the foregoing modules to perform an operation corresponding to the module.

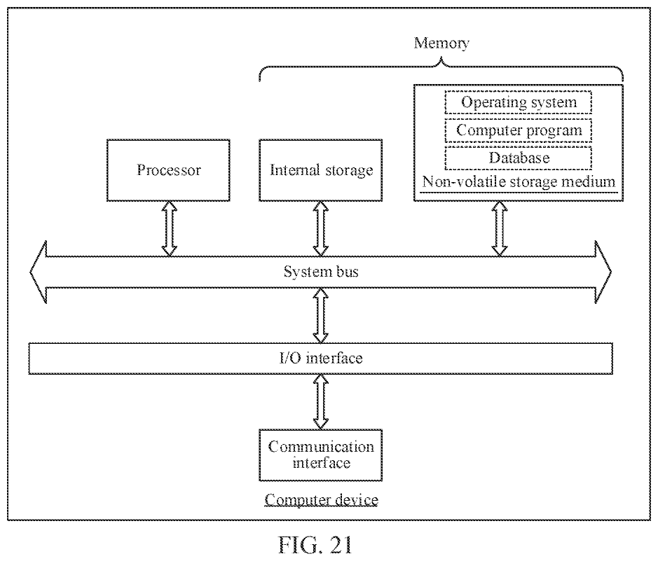

In an embodiment, a computer device is provided. The computer device may be a server. An internal structure diagram of the server may be shown in FIG. 21. The computer device includes a processor, a storage, an input/output (I/O for short) interface, and a communication interface. The processor, the memory, and the I/O interface are connected through a system bus, and the communication interface is connected to the system bus through the I/O interface. The processor of the computer device is configured to provide computing and control capabilities. The memory of the computer device includes a non-volatile storage medium and an internal memory. The non-volatile storage medium has an operating system, a computer-readable instruction, and a database stored therein. The internal memory provides an environment for running of the operating system and the computer-readable instruction in the non-volatile storage medium. The I/O interface of the computer device is configured to exchange information between the processor and an external device. The communication interface of the computer device is configured to connect to and communicate with an external terminal through a network. The computer-readable instruction, when executed by the processor, implements a write data signal delay control method.

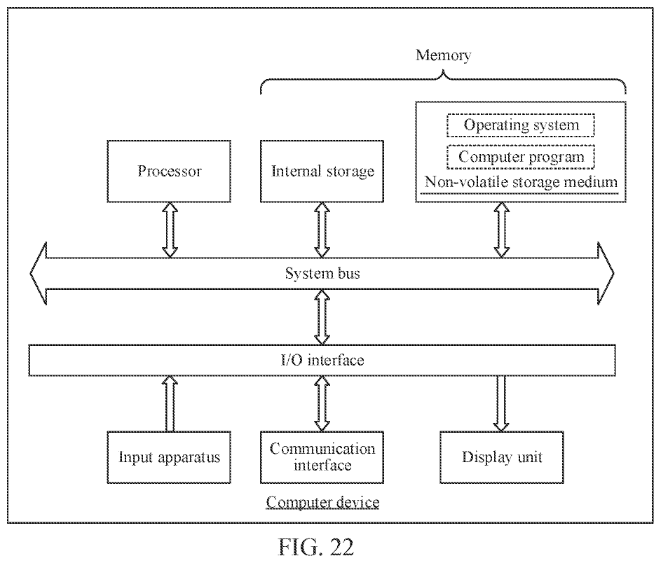

In an embodiment, a computer device is provided. The computer device may be a terminal. An internal structure diagram of the terminal may be shown in FIG. 22. The computer device includes a processor, a memory, an I/O interface, a communication interface, a display unit, and an input apparatus. The processor, the memory, and the I/O interface are connected through a system bus. The communication interface, the display unit, and the input apparatus are connected to the system bus through the I/O interface. The processor of the computer device is configured to provide computing and control capabilities. The memory of the computer device includes a non-volatile storage medium and an internal memory. The non-volatile storage medium has an operating system and a computer-readable instruction stored therein. The internal memory provides an environment for running of the operating system and the computer-readable instruction in the non-volatile storage medium. The I/O interface of the computer device is configured to exchange information between the processor and an external device. The communication interface of the computer device is used for wired or wireless communication with an external terminal. The wireless communication may be implemented through Wi-Fi, a mobile cellular network, near field communication (NFC), or other technologies. The computer-readable instruction, when executed by the processor, implements a write data signal delay control method. The display unit of the computer device is configured to form a visually visible picture, and may be a display screen, a projection apparatus, or a virtual reality imaging apparatus. The display screen may be a liquid crystal display screen or an electronic ink display screen. The input apparatus of the computer device may be a touch layer covering the display screen, or may be a key, a trackball, or a touch pad arranged on a housing of the computer device, and may further be an external keyboard, a touch pad, a mouse, or the like.

A person skilled in the art may understand that, the structures shown in FIG. 21 and FIG. 22 are merely block diagrams of partial structures related to the solutions in this application, and do not constitute a limitation on the computer device to which the solution in this application is applied. Specifically, the computer device may include more or fewer components than those shown in the figure, or some merged components, or different component arrangements.

In an embodiment, a computer device is further provided, including a memory and one or more processors. The memory has computer-readable instructions stored therein. The one or more processors, when executing the computer-readable instructions, implement the steps in the foregoing method embodiments.

In an embodiment, one or more non-transitory computer-readable storage media are provided, having computer-readable instructions stored therein. The computer-readable instructions, when executed by one or more processors, implement the steps in the foregoing method embodiments.

In an embodiment, a computer program product is further provided, including a computer-readable instruction, the computer-readable instruction, when executed by one or more processors, implementing the steps in the foregoing method embodiments.

User information (including but not limited to user equipment information, user personal information, and the like) and data (including but not limited to data for analysis, stored data, displayed data, and the like) involved in this application are all information and data authorized by users or fully authorized by all parties. The collection, use, and processing of relevant data need to comply with the relevant laws, regulations, and standards of relevant countries and regions.

A person of ordinary skill in the art may understand that all or some of processes of the method in the foregoing embodiments may be performed by using a computer-readable instruction to instruct relevant hardware. The computer-readable instruction may be stored in a non-volatile computer-readable storage medium. When the computer-readable instruction is executed, the processes of the foregoing method embodiments may be included. Any reference to the memory, the storage medium, the database, or other media used in the embodiments provided in this application may include at least one of a non-volatile memory and a volatile memory. The non-volatile memory may include a read-only memory (ROM), a magnetic tape, a floppy disk, a flash memory, an optical memory, or the like. The volatile memory may include a RAM or an external cache. As a description rather than a limitation, the RAM may have various forms, such as a static RAM (SRAM) or a dynamic RAM (DRAM).

The technical features of the foregoing embodiments may be randomly combined. To make the description concise, not all possible combinations of the technical features in the foregoing embodiments are described. However, the combinations of these technical features are considered as falling within the scope recorded in this specification provided that no conflict exists.

The foregoing embodiments describe only some implementations of this application, which are described specifically and in detail, but cannot be construed as a limitation on the scope of the invention patent. For a person of ordinary skill in the art, some transformations and improvements may be made without departing from the idea of this application. These transformations and improvements belong to the protection scope of this application. Therefore, the protection scope of the patent of this application is subject to the appended claims. In this application, the term “module” or “unit” in this application refers to a computer program or part of the computer program that has a predefined function and works together with other related parts to achieve a predefined goal and may be all or partially implemented by using software, hardware (e.g., processing circuitry and/or memory configured to perform the predefined functions), or a combination thereof. Each module or unit can be implemented using one or more processors (or processors and memory). Likewise, a processor (or processors and memory) can be used to implement one or more modules or units. Moreover, each module or unit can be part of an overall module that includes the functionalities of the module.

What is claimed is:

1. A write data signal delay control method, performed by a computer device, the method comprising:
configuring an operating mode of a register circuit in a memory by using a host, to obtain a training register that supports reading and writing;
transmitting a sample write data signal to the memory by using the host;
sampling the sample write data signal based on a sampling signal by using the memory;
caching a sampled write data signal obtained from the sampling of the sample write data signal into the training register; and
performing delay adjustment training on a write data delay control circuit arranged on the host based on the sample write data signal when the sampled write data signal read by the host from the training register is inconsistent with the sample write data signal.

2. The method according to claim 1, wherein the method further comprises:
performing signal offset adjustment on an inputted write data signal by using the trained write data delay control circuit, to obtain a target write data signal aligned with a sampling edge of the sampling signal, the target write data signal being to be written to the memory.

3. The method according to claim 1, wherein the configuring an operating mode of a register circuit in a memory by using a host, to obtain a training register that supports reading and writing comprises:
setting a value of a mode register in the memory to a target value by using the host, the target value being a value corresponding to a read-write mode supported by the register circuit; and
controlling, by using the target value, the register circuit to operate in the read-write mode, to obtain the training register that supports reading and writing.

4. The method according to claim 1, wherein the sample write data signal comprises a plurality of subsample signals; the write data delay control circuit arranged on the host comprises a plurality of subcircuits, one of the subcircuits being configured to control a delay of one of the subsample signals.

5. The method according to claim 4, wherein the performing delay adjustment training on a write data delay control circuit arranged on the host based on the sample write data signal, to obtain a trained write data delay control circuit comprises:
performing, for each subcircuit in the write data delay control circuit, single-circuit delay adjustment training on the subcircuit based on the subsample signal corresponding to the subcircuit, to obtain a trained initial subcircuit, the subsample signal on which the signal offset adjustment is performed by using the initial subcircuit being aligned with the sampling edge of the sampling signal; and
performing multi-circuit delay adjustment training on each initial subcircuit based on the plurality of subsample signals, to obtain the trained write data delay control circuit, the trained write data delay control circuit comprising a plurality of trained target subcircuits, each subsample signal on which the signal offset adjustment is performed by using each of the target subcircuits being aligned with a same sampling edge of the sampling signal.

6. The method according to claim 1, wherein the method further comprises:
monitoring a system operating state of a high-bandwidth memory system, the high-bandwidth memory system comprising the host and the memory; and
when the system operating state is an unbusy state, reperforming the operation of configuring the operating mode of the register circuit in the memory by using the host, to obtain the training register for caching data, to trigger re-performing of the delay adjustment training.

7. The method according to claim 1, wherein the transmitting a sample write data signal to the memory by using the host comprises:
transmitting, to the memory by using the host, the sample write data signal and a write data selection pulse signal matching the sample write data signal; and
sampling the sample write data signal based on the write data selection pulse signal by using the memory.

8. A computer device, comprising a memory and one or more processors, the memory storing a computer-readable instruction that, when executed by the one or more processors, causes the computer device to implement a write data signal delay control method including:
configuring an operating mode of a register circuit in a memory by using a host, to obtain a training register that supports reading and writing;
transmitting a sample write data signal to the memory by using the host;
sampling the sample write data signal based on a sampling signal by using the memory;
caching a sampled write data signal obtained from the sampling of the sample write data signal into the training register; and
performing delay adjustment training on a write data delay control circuit arranged on the host based on the sample write data signal when the sampled write data signal read by the host from the training register is inconsistent with the sample write data signal.

9. The computer device according to claim 8, wherein the method further comprises:
performing signal offset adjustment on an inputted write data signal by using the trained write data delay control circuit, to obtain a target write data signal aligned with a sampling edge of the sampling signal, the target write data signal being to be written to the memory.

10. The computer device according to claim 8, wherein the configuring an operating mode of a register circuit in a memory by using a host, to obtain a training register that supports reading and writing comprises:
setting a value of a mode register in the memory to a target value by using the host, the target value being a value corresponding to a read-write mode supported by the register circuit; and
controlling, by using the target value, the register circuit to operate in the read-write mode, to obtain the training register that supports reading and writing.

11. The computer device according to claim 8, wherein the sample write data signal comprises a plurality of subsample signals; the write data delay control circuit arranged on the host comprises a plurality of subcircuits, one of the subcircuits being configured to control a delay of one of the subsample signals.

12. The computer device according to claim 11, wherein the performing delay adjustment training on a write data delay control circuit arranged on the host based on the sample write data signal, to obtain a trained write data delay control circuit comprises:
performing, for each subcircuit in the write data delay control circuit, single-circuit delay adjustment training on the subcircuit based on the subsample signal corresponding to the subcircuit, to obtain a trained initial subcircuit, the subsample signal on which the signal offset adjustment is performed by using the initial subcircuit being aligned with the sampling edge of the sampling signal; and
performing multi-circuit delay adjustment training on each initial subcircuit based on the plurality of subsample signals, to obtain the trained write data delay control circuit, the trained write data delay control circuit comprising a plurality of trained target subcircuits, each subsample signal on which the signal offset adjustment is performed by using each of the target subcircuits being aligned with a same sampling edge of the sampling signal.

13. The computer device according to claim 8, wherein the method further comprises:
monitoring a system operating state of a high-bandwidth memory system, the high-bandwidth memory system comprising the host and the memory; and
when the system operating state is an unbusy state, reperforming the operation of configuring the operating mode of the register circuit in the memory by using the host, to obtain the training register for caching data, to trigger re-performing of the delay adjustment training.

14. The computer device according to claim 8, wherein the transmitting a sample write data signal to the memory by using the host comprises:
transmitting, to the memory by using the host, the sample write data signal and a write data selection pulse signal matching the sample write data signal; and
sampling the sample write data signal based on the write data selection pulse signal by using the memory.

15. One or more non-transitory computer-readable storage media, having computer-readable instructions stored therein, the computer-readable instructions, when executed by one or more processors of a computer device, causing the computer device to implement a write data signal delay control method including:
configuring an operating mode of a register circuit in a memory by using a host, to obtain a training register that supports reading and writing;
transmitting a sample write data signal to the memory by using the host;
sampling the sample write data signal based on a sampling signal by using the memory;
caching a sampled write data signal obtained from the sampling of the sample write data signal into the training register; and
performing delay adjustment training on a write data delay control circuit arranged on the host based on the sample write data signal when the sampled write data signal read by the host from the training register is inconsistent with the sample write data signal.

16. The non-transitory computer-readable storage media according to claim 15, wherein the method further comprises:
performing signal offset adjustment on an inputted write data signal by using the trained write data delay control circuit, to obtain a target write data signal aligned with a sampling edge of the sampling signal, the target write data signal being to be written to the memory.

17. The non-transitory computer-readable storage media according to claim 15, wherein the configuring an operating mode of a register circuit in a memory by using a host, to obtain a training register that supports reading and writing comprises:
setting a value of a mode register in the memory to a target value by using the host, the target value being a value corresponding to a read-write mode supported by the register circuit; and
controlling, by using the target value, the register circuit to operate in the read-write mode, to obtain the training register that supports reading and writing.

18. The non-transitory computer-readable storage media according to claim 15, wherein the sample write data signal comprises a plurality of subsample signals; the write data delay control circuit arranged on the host comprises a plurality of subcircuits, one of the subcircuits being configured to control a delay of one of the subsample signals.

19. The non-transitory computer-readable storage media according to claim 15, wherein the method further comprises:
monitoring a system operating state of a high-bandwidth memory system, the high-bandwidth memory system comprising the host and the memory; and
when the system operating state is an unbusy state, reperforming the operation of configuring the operating mode of the register circuit in the memory by using the host, to obtain the training register for caching data, to trigger re-performing of the delay adjustment training.

20. The non-transitory computer-readable storage media according to claim 15, wherein the transmitting a sample write data signal to the memory by using the host comprises:
transmitting, to the memory by using the host, the sample write data signal and a write data selection pulse signal matching the sample write data signal; and
sampling the sample write data signal based on the write data selection pulse signal by using the memory.
